(19) United States
(12) Patent Application Publication
(10) Pub. No.: US 2026/0026176 A1
(43) Pub. Date: Jan. 22, 2026

(54) DISPLAY DEVICE AND MANUFACTURE METHOD THEREOF

(71) Applicant: LG Display Co., Ltd., Seoul (KR)

(72) Inventors: Sujin JEONG, Siheung-si (KR); Danlyoul MA, Seoul (KR); Hyoungsun PARK, Seoul (KR); Hyunseok NA, Hwaseong-si (KR); Bongsoo JEON, Hwaseong-si (KR)

(73) Assignee: LG Display Co., Ltd., Seoul (KR)

(21) Appl. No.: 19/224,007

(22) Filed: May 30, 2025

(30) Foreign Application Priority Data
Jul. 19, 2024 (KR) 10-2024-0095560

(51) Int. Cl. H10H 29/854; H01L 25/16; H10H 29/01; H10H 29/37

(52) U.S. Cl. CPC H10H 29/854; H01L 25/167; H10H 29/0362; H10H 29/37

(57) ABSTRACT

A display device and a manufacture method thereof are discussed. The display device can include a substrate, an adhesive layer disposed on the substrate, a driving chip disposed on the adhesive layer, a first planarization layer disposed on the adhesive layer to surround a lower portion of a side surface of the driving chip, a second planarization layer disposed on the first planarization layer to surround an upper portion of the side surface of the driving chip, and at least one protective film disposed between the second planarization layer and the driving chip to cover at least the upper portion of the side surface of the driving chip.

### CROSS-REFERENCE TO RELATED APPLICATION

This application claims priority to Korean Patent Application No. 10-2024-0095560 filed on Jul. 19, 2024 in the Korean Intellectual Property Office, and all the benefits accruing therefrom under 35 U.S.C. 119, the contents of which in its entirety are herein expressly incorporated by reference into the present application.

### BACKGROUND

### Field

The present disclosure relates to a display device and more specifically, for example, without limitation, to a display device capable of preventing penetration of moisture and chemical solutions into a driving chip and preventing a structural defect around the driving chip and to a manufacture method thereof.

### Description of the Related Art

Display devices are applied to various electronic devices such as TV, mobile phones, laptops, and tablets.

The display device includes an organic light-emitting display device (OLED) that emits light by itself, and a liquid crystal display device (LCD) that requires a separate light source.

Recently, a display device including a light-emitting diode (LED) has attracted attention as a next-generation display device. Since the light-emitting diode is made of an inorganic material rather than an organic material, the display device including the light-emitting diode can have a faster lighting speed than that of the liquid crystal display device or the organic light-emitting display device, and can have excellent luminous efficiency, and can display an image with high luminance.

The description provided in the description of the related art section should not be assumed to be prior art merely because it is mentioned in or associated with the description of the related art section. The description of the related art section can include information that describes one or more aspects of the subject technology, and the description in this section does not limit the disclosure.

### SUMMARY OF THE DISCLOSURE

The inventors have realized that in related art, the driving chip can be affected by moisture and chemical solutions and deteriorate. Accordingly, a purpose of the present disclosure is to provide a display device capable of preventing or minimizing penetration of moisture and chemical solutions into a driving chip and preventing or minimizing a structural defect around the driving chip.

Purposes according to the present disclosure are not limited to the above-mentioned purpose. Other purposes and advantages according to the present disclosure that are not mentioned can be understood based on following descriptions, and can be more clearly understood based on example embodiments according to the present disclosure. Further, it will be easily understood that the purposes and advantages according to the present disclosure can be realized using means shown in the claims or combinations thereof.

A display device according to one example embodiment of the present disclosure includes: a substrate; an adhesive layer disposed on the substrate; a driving chip disposed on the adhesive layer; a first planarization layer disposed on the adhesive layer so as to surround a lower portion of a side surface of the driving chip; a second planarization layer disposed on the first planarization layer so as to surround an upper portion of the side surface of the driving chip; and at least one protective film disposed between the second planarization layer and the driving chip so as to cover at least the upper portion of the side surface of the driving chip.

A manufacture method of a display device according to one example embodiment of the present disclosure includes: forming a substrate; forming an adhesive layer over the substrate; forming a driving chip on the adhesive layer; forming a first planarization layer on the adhesive layer so as to surround a lower portion of a side surface of the driving chip; and forming a second planarization layer on the first planarization layer so as to surround an upper portion of the side surface of the driving chip, wherein at least one protective film is formed between the second planarization layer and the driving chip so as to cover at least the upper portion of the side surface of the driving chip.

According to an example embodiment of the present disclosure, the penetration of moisture and a chemical solution into the driving chip disposed in the display area can be prevented, and the structural defect around the driving chip can be prevented.

According to an example embodiment of the present disclosure, in addition to the above-described effect, the adhesive strength between the first planarization layer and the second planarization layer surrounding the driving chip is enhanced, so that the second planarization layer and the first planarization layer can be prevented to being peeled off from each other.

According to an example embodiment of the present disclosure, the structural defect around the driving chip and peeling-off of the planarization layer are prevented, so that a defect rate of the display device is lowered, thereby reducing production energy required for manufacturing the display device and reducing greenhouse gas emission.

Effects of the present disclosure are not limited to the effects mentioned above, and other effects not mentioned will be clearly understood by those skilled in the art from the description as set forth below.

In addition to the above effects, specific effects of the present disclosure are described together while describing specific details for carrying out the present disclosure.

### BRIEF DESCRIPTION OF DRAWINGS

The above and other objects, features, and advantages of the present disclosure will become more apparent to those of ordinary skill in the art by describing example embodiments thereof in detail with reference to the attached drawings, in which:

FIG. 1 is an exploded perspective view of a display device according to an example embodiment of the present disclosure.

FIG. 2 is a plan view of a display device according to an example embodiment of the present disclosure.

FIG. 3 is an enlarged view of a display device according to an example embodiment of the present disclosure.

FIG. 4 is a diagram illustrating a circuit structure according to an example embodiment of the present disclosure.

FIG. 5 is a plan view of a display device according to an example embodiment of the present disclosure.

FIG. 6 is a plan view of a display device according to an example embodiment of the present disclosure.

FIG. 7 is a plan view of a display device according to an example embodiment of the present disclosure.

FIG. 8 is a cross-sectional view of a display device according to an example embodiment of the present disclosure.

FIG. 9 is a cross-sectional view of a display device according to an example embodiment of the present disclosure.

FIG. 10, FIG. 11, FIG. 12 and FIG. 13 are diagrams illustrating an apparatus to which a display device according to example embodiments of the present disclosure is applied.

FIG. 14 is a plan view of a display device according to an example embodiment of the present disclosure.

FIG. 15 is a plan view illustrating an area in which one pixel driving circuit among a plurality of pixel driving circuits of FIG. 14 is disposed.

FIG. 16 is a diagram illustrating a touch operation of a display device according to an example embodiment of the present disclosure.

FIG. 17 illustrates an example signal waveform diagram when a display device according to an example embodiment of the present disclosure operates.

FIG. 18 is a cross-sectional view taken along a cutting line XVIII-XVIII of FIG. 14.

FIG. 19 is an enlarged view of an ‘A’ area of FIG. 18.

FIG. 20 is a plan view showing the ‘A’ area.

FIG. 21 is a drawing showing a method for manufacturing a display device according to an example embodiment of the present disclosure.

FIG. 22 is a cross-sectional view showing a display device according to an example embodiment of the present disclosure, and is a cross-sectional view corresponding to FIG. 19.

FIG. 23 is a cross-sectional view showing a display device according to an example embodiment of the present disclosure, and is a cross-sectional view corresponding to FIG. 19.

FIG. 24 is a cross-sectional view showing a display device according to an example embodiment of the present disclosure, and is a cross-sectional view corresponding to FIG. 19.

FIG. 25 is a plan view showing a display device according to an example embodiment of the present disclosure, and is a plan view corresponding to FIG. 20.

FIG. 26 is a cross-sectional view showing a display device according to an example embodiment of the present disclosure, and is a cross-sectional view corresponding to FIG. 22.

FIG. 27 is a cross-sectional view showing a display device according to an example embodiment of the present disclosure, and is a cross-sectional view corresponding to FIG. 23.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Advantages and features of the present disclosure, and a method of achieving the advantages and features will become apparent with reference to embodiments described below in detail together with the accompanying drawings. However, the present disclosure is not limited to the embodiments as disclosed under, but can be implemented in various different forms. Thus, these embodiments are set forth only to make the present disclosure complete, and to entirely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as can be included within the spirit and scope of the present disclosure as defined by the appended claims. Shapes, sizes, dimensions (e.g., length, width, height, thickness, radius, diameter, area, etc.), ratios, angles, numbers, etc. disclosed in the drawings for illustrating embodiments of the present disclosure are illustrative, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “include,” “have,” “comprise,” “contain,” “constitute,” “make up of,” “formed of,” and “consist of” when used in this disclosure, specify the presence of the stated features, integers, operations, elements, components and/or portions thereof, but do not preclude the presence or addition of one or more other features, integers, operations, elements, components, and/or portions thereof. As used herein, the term “and/or” includes any and all combinations of one or more of associated listed items.

Expression such as “at least one of” when preceding a list of elements can modify an entirety of the list of elements and may not modify the individual elements of the list.

In interpretation of numerical values, an error or tolerance therein can occur even when there is no explicit description thereof.

In addition, it will also be understood that when a first element or first layer is referred to as being present “on” a second element or second layer, the first element can be disposed directly on the second element or can be disposed indirectly on the second element with a third element or layer being disposed between the first and second elements or layers. It will be understood that when a first element or first layer is referred to as being “connected to”, or “coupled to” a second element or second layer, the first element or first layer can be directly connected to or coupled to the second element or layer, or one or more intervening elements or layers can be present therebetween. In addition, it will also be understood that when an element or layer is referred to as being “between” two elements or layers, it can be the only element or layer between the two elements or layers, or one or more intervening elements or layers can also be present therebetween.

Further, as used herein, when a layer, film, area, plate, or the like is disposed “on” or “on a top” of another layer, film, area, plate, or the like, the former can directly contact the latter or still another layer, film, area, plate, or the like can be disposed between the former and the latter. As used herein, when a layer, film, area, plate, or the like is directly disposed “on” or “on a top” of another layer, film, area, plate, or the like, the former directly contacts the latter and still another layer, film, area, plate, or the like is not disposed between the former and the latter. Further, as used herein, when a layer, film, area, plate, or the like is disposed “below” or “under” another layer, film, arca, plate, or the like, the former can directly contact the latter or still another layer, film, area, plate, or the like can be disposed between the former and the latter. As used herein, when a layer, film, area, plate, or the like is directly disposed “below” or “under” another layer, film, arca, plate, or the like, the former directly contacts the latter and still another layer, film, area, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is indicated. When a certain embodiment can be implemented differently, a function or an operation specified in a specific block can occur in a different order from an order specified in a flowchart. For example, two blocks in succession can be actually performed substantially concurrently, or the two blocks can be performed in a reverse order depending on a function or operation involved.

It will be understood that, although the terms “first”, “second”, “third”, and so on can be used herein to describe various elements, components, areas, layers and/or periods, these elements, components, areas, layers and/or periods should not be limited by these terms. These terms are used to distinguish one element, component, area, layer or section from another element, component, area, layer or section. Thus, a first element, component, area, layer or section as described under could be termed a second element, component, area, layer or section, without departing from the spirit and scope of the present disclosure.

A term “device” used herein can refer to a display device including a display panel and a driver for driving the display panel. Examples of the display device can include a light emitting element, and the like. In addition, examples of the device can include a notebook computer, a television, a computer monitor, an automotive device, a wearable device, and an automotive equipment device, and a set electronic device (or apparatus) or a set device (or apparatus), for example, a mobile electronic device such as a smartphone or an electronic pad, which are complete products or final products respectively including light emitting element and the like, but embodiments of the present disclosure are not limited thereto.

When an embodiment can be implemented differently, functions or operations specified within a specific block can be performed in a different order from an order specified in a flowchart. For example, two consecutive blocks can actually be performed substantially simultaneously, or the blocks can be performed in a reverse order depending on related functions or operations. The features of the various embodiments of the present disclosure can be partially or entirely combined with each other, and can be technically associated with each other or operate with each other. The embodiments can be implemented independently of each other and can be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects, etc. should not be construed such that any aspect or design as described is superior to or advantageous over other aspects or designs. Further, the term ‘or’ means ‘inclusive or’ rather than ‘exclusive or’. For example, unless otherwise stated or clear from the context, the expression that ‘x uses a or b’ means one of natural inclusive permutations.

The terms used in the description as set forth below have been selected as being general and universal in the related technical field. However, there can be other terms than the terms depending on the development and/or change of technology, convention, preference of technicians, etc. Therefore, the terms used in the description as set forth below should not be understood as limiting technical ideas, but should be understood as examples of the terms for illustrating embodiments. Further, in a specific case, a term can be arbitrarily selected by the applicant, and in this case, the detailed meaning thereof will be described in a corresponding description period. Therefore, the terms used in the description as set forth below should be understood based on not simply the name of the terms, but the meaning of the terms and the contents throughout the Detailed Descriptions.

In description of flow of a signal, for example, when a signal is delivered from a node A to a node B, this can include a case where the signal is transferred from the node A to the node B via another node unless a phrase ‘immediately transferred’ or ‘directly transferred’ is used. Throughout the present disclosure, “A and/or B” means A, B, or A and B, unless otherwise specified, and “C to D” means C inclusive to D inclusive unless otherwise specified.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but can be interpreted as having a geometric relationship with each other in which the first direction, the second direction, and the third direction interest each other at an angle other than 90 degrees or the X-axis direction, the Y-axis direction, and the Z-axis direction are interest each other at an angle other than 90 degrees within a range in which a configuration of the present disclosure can work functionally.

When a first component or layer is described as “contacting” or “overlapping” a second component or layer, it should be understood that the first component or layer can directly contact or overlap the second component or layer, or a third component or layer can be interposed between the first and second components or layers that can indirectly contact or overlap each other unless otherwise specified. Further, the term “can” fully encompasses all the meanings and coverages of the term “may” and vice versa.

Hereinafter, various example embodiments of the present disclosure will be described in detail with reference to the accompanying drawings. All the components of each display device according to all embodiments of the present disclosure are operatively coupled and configured.

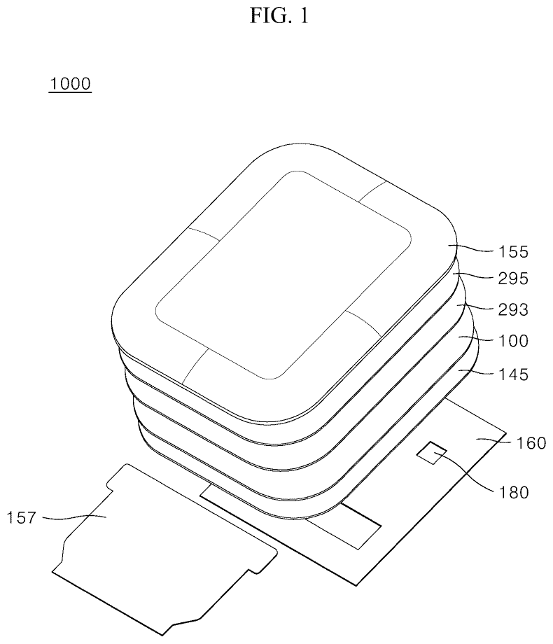

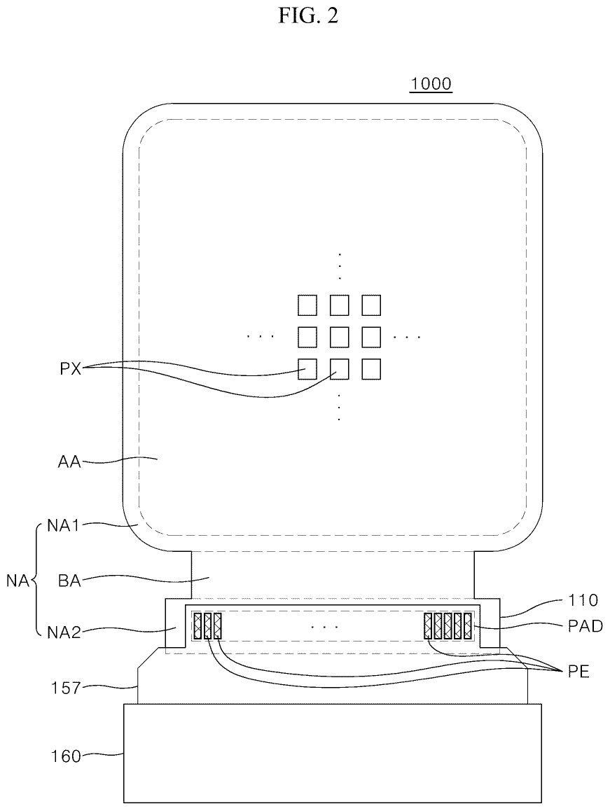

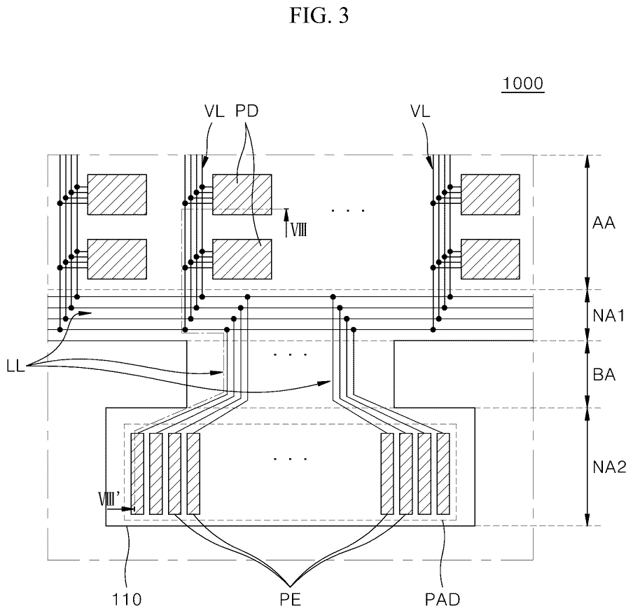

FIG. 1 is an exploded perspective view of a display device according to an example embodiment of the present disclosure. FIG. 2 is a plan view of a display device according to an example embodiment of the present disclosure. FIG. 3 is an enlarged view of a display device according to an example embodiment of the present disclosure.

Referring to FIGS. 1 to 3, a display device 1000 according to an example embodiment of the present disclosure can include a display panel 100, a polarizing layer 293, an adhesive layer 295, a cover member 155, a support substrate 145, a flexible circuit board 157, and a printed circuit board 160.

For example, the display device 1000 can include a substrate 110. The substrate 110 can be a member that supports other components of the display device 1000. The substrate 110 can be made of an insulating material. For example, the substrate 110 can be made of glass or resin. Alternatively, the substrate 110 can be made of a material having flexibility. For example, the substrate can include a flexible polymer film. For example, the flexible polymer film can be made of any one of polyimide (PI), polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto. For example, the substrate 110 can be made of a plastic material having flexibility, such as polyimide (PI). However, the example embodiments of the present disclosure are not limited thereto.

The display panel 100 can implement information, video, and/or images to be provided to a user. For example, the display panel 100 can include a display area AA (or active area) and a non-display area NA (or non-active area). For example, the substrate 110 can include the display area AA and the non-display area NA. The distinction between the display area AA and non-display area NA are applied not only to the substrate 110 but may also be applied to the entire display device 1000.

The display area AA can be an area where an image is displayed. The display area AA can include a plurality of pixels PX. Each of the plurality of pixels PX can be constituted with a plurality of sub-pixels. At each of the plurality of sub-pixels a plurality of light-emitting elements can be disposed. The plurality of light-emitting elements can be configured differently depending on the kinds of display device 1000. For example, in a case where the display device 1000 is an inorganic light-emitting display device, the light-emitting element can be a light-emitting diode (LED), a micro light-emitting diode (LED), or a mini light-emitting diode (LED). However, the example embodiments of the present disclosure are not limited thereto.

The non-display area NA can be an area where an image is not displayed. In the non-display area NA, various wirings and circuits for driving a plurality of pixels PX in the display area AA can be disposed. For example, various wires and driving circuits can be mounted in the non-display area NA, and a pad part PAD to which integrated circuits and printed circuits are connected can be disposed in the non-display area NA. However, the example embodiments of the present disclosure are not limited thereto.

For example, the driving circuit can be a data driving circuit and/or a gate driving circuit. However, the example embodiments of the present disclosure are not limited thereto. In the non-display area NA, there can be disposed wirings through which control signals for controlling the driving circuits are supplied. For example, the control signal can include various timing signals including synchronization signals, an input data enable signal, and a clock signal. Here, the horizontal synchronization signal is a signal representing a time taken to display one horizontal line of a screen and the vertical synchronization signal is a signal representing a time taken to display a screen of one frame. The input data enable signal can correspond to a signal indicating a period for which a data voltage is supplied to the pixel. However, the example embodiments of the present disclosure are not limited thereto. The control signal can be received through the pad part PAD. For example, in the non-display area NA, there can be disposed link lines LL for transmitting a signal. For example, driving components such as the flexible circuit board 157 and the printed circuit board 160 can be connected to the pad part PAD.

According to the present disclosure, the non-display area NA can include a first non-display area NA1, a bending area BA, and a second non-display area NA2. For example, the first non-display area NA1 can be an area surrounding at least a portion of the display area AA. The bending area BA can be an area which is bendable and extends from at least one of a plurality of sides of the first non-display area NA1. The second non-display area NA2 can be an area which extends from the bending area BA, and in which the pad part PAD can be disposed. For example, the bending area BA can be in a bent state, and the remaining area of the substrate 110 except the bending area BA can be in a flat state. In this case, as the bending area BA is bent, the second non-display area NA2 can be located on the rear surface of the display area AA. However, the example embodiments of the present disclosure are not limited thereto.

For example, the non-display area NA can include a first non-display area, a second non-display area, a third non-display area, and a fourth non-display area. The first non-display area can be located outside of the display area AA in the column direction. The second non-display area can be located outside of the display area AA in a row direction (or first direction). The third non-display area can be located outside of the display area AA in the column direction (or second direction) and located opposite to the first non-display area. The fourth non-display area can be located outside of the display area AA in the row direction and located opposite to the second non-display area. The first non-display area among the first to fourth non-display areas can include a pad area to which a driving circuit is connected or bonded. The second to fourth non-display areas that do not include the pad area among the first to fourth non-display areas can have a very small size, but aspects of the present disclosure are not limited thereto.

The display area AA of the substrate 110 or the display device 1000 can be configured in various shapes depending on the designs of the display device 1000. For example, the display area AA can be configured in a rectangular shape with four rounded corners. However, the example embodiments of the present disclosure are not limited thereto. For another example, the display area AA can be configured in a rectangular shape with four right-angled corners, a circular shape, or the like. However, the example embodiments of the present disclosure are not limited thereto.

According to the present disclosure, the width of the second non-display area NA2 in which a plurality of pad electrodes PE are disposed can be greater than the width of the bending area BA in which only the plurality of link lines LL are disposed. Additionally, the width of the display area AA in which the plurality of sub-pixels are disposed can be greater than the width of the bending area BA in which only the plurality of link lines LL are disposed. Although the width of the bending area BA is depicted in the drawing as being smaller than the widths of other areas of the substrate 110, the shape of the substrate 110 including such bending area BA is only an example, and the example embodiments of the present disclosure are not limited thereto.

Referring to FIG. 3, a plurality of pixel driving circuits PD can be disposed in the display area AA. The plurality of pixel driving circuits PD can be circuits for driving light-emitting elements of a plurality of sub-pixels. Each of the plurality of pixel driving circuits PD can include a plurality of transistors including a driving transistor, a storage capacitor and the like, and can control the light-emitting operation of the plurality of light-emitting elements by supplying a control signal, power, and a driving current to the light-emitting elements of the plurality of sub-pixels. For example, a pixel driving circuit PD can include a power line and a signal line for controlling the on/off and/or light-emitting time of a light-emitting element. For example, the plurality of pixel driving circuits PD can be driving chips manufactured on a semiconductor substrate using a metal-oxide-silicon field effect transistor (MOSFET) manufacturing process. However, the example embodiments of the present disclosure are not limited thereto. The driving chip can include a plurality of pixel driving circuits PD, and can drive a plurality of sub-pixels. For example, the plurality of pixel driving circuits PD can belong to a micro driver, which is a kind of a driving chip having a size of several tens of um to several hundreds of um. However, the example embodiments of the present disclosure are not limited thereto.

Referring to FIG. 1 together, the flexible circuit board 157 and the printed circuit board 160 can be disposed at the lower side of the display panel 100. The flexible circuit board 157 and the printed circuit board 160 can be disposed at least on one edge of the display panel 100. However, the example embodiments of the present disclosure are not limited thereto. One side of the flexible circuit board 157 can be attached to the display panel 100, and the other side thereof can be attached to the printed circuit board 160. However, the example embodiments of the present disclosure are not limited thereto. The flexible circuit board 157 can be made of a flexible film. However, the example embodiments of the present disclosure are not limited thereto.

In the second non-display area NA2, the pad part PAD can be disposed which includes the plurality of pad electrodes PE. To the pad part PAD a driving component including one or more flexible circuit boards (or flexible films) 157 and the printed circuit boards 160 can be attached or bonded. The plurality of pad electrodes PE of the pad part PAD can be electrically connected to one or more flexible circuit boards (or flexible films) 157 to transmit various signals or power from the printed circuit board 160 and the flexible circuit board (or flexible film) 157 to the plurality of pixel driving circuits PD in the display area AA.

The flexible circuit board (or flexible film) 157 can be a film in which various components are disposed on a flexible base film. For example, a driving IC such as a gate driver IC or a data driver IC can be disposed on the flexible circuit board (or flexible film) 157. However, the example embodiments of the present disclosure are not limited thereto. The driving IC can be a kind of a component that processes data and driving signals for displaying an image. The driving IC can be disposed in a manner such as a Chip On Glass (COG), a Chip On Film (COF), or a Tape Carrier Package (TCP) depending on the mounting method. However, the example embodiments of the present disclosure are not limited thereto. The flexible circuit board (or flexible film) 157 can be attached or bonded onto the plurality of pad electrodes PE via a conductive adhesive layer. However, the example embodiments of the present disclosure are not limited thereto.

The printed circuit board 160 can be a kind of a component electrically connected to one or more flexible circuit boards (or flexible films) 157 to supply signals to the driving IC. The printed circuit board 160 can be disposed at one side of the flexible circuit board (or flexible film) 157 to be electrically connected to the flexible circuit board (or flexible film) 157. Various components for supplying various signals to the driving IC can be disposed on the printed circuit board 160. For example, a variety of components, including a timing controller, a power supply, a memory, a processor, or the like can be disposed on the printed circuit board 160. For example, the printed circuit board 160 can be provided with a power management integrated circuit (PMIC). However, the example embodiments of the present disclosure are not limited thereto.

The printed circuit board 160 can include at least one hole 180. However, the example embodiments of the present disclosure are not limited thereto. In an area corresponding to at least one hole 180, there can be disposed an internal component detecting ambient light, temperature or the like. The internal component can include a plurality of sensors. For example, the internal component can include an ambient light sensor (ALS) or a temperature sensor. However, example embodiments of the present disclosure are not limited thereto. For example, the hole 180 can be a through hole. However, the example embodiments of the present disclosure are not limited thereto.

Referring to FIG. 1, the polarizing layer 293 can be disposed on the display panel 100. The polarizing layer 293 can prevent or alleviate a phenomenon in which the light generated by an external light source enters the display panel 100 and affects the light-emitting element or the like. The polarizing layer 293 can prevent or alleviate external light reflection by components of the display panel 100.

The cover member 155 can be disposed on the polarizing layer 293. The cover member 155 can be a member for protecting the display panel 100. The adhesive layer 295 can be disposed between the polarizing layer 293 and the cover member 155. By the adhesive layer 295 the cover member 155 can be attached to the polarizing layer 293. The adhesive layer 295 can include an optically clear adhesive (OCA), an optically clear resin (OCR), a pressure sensitive adhesive (PSA), or the like. However, the example embodiments of the present disclosure are not limited thereto.

The support substrate 145 can be disposed between the display panel 100 and the printed circuit board 160. The support substrate 145 can reinforce the rigidity of the display panel 100. The support substrate 145 can be a back plate. However, the example embodiments of the present disclosure are not limited thereto.

Referring to FIGS. 1 to 3, the plurality of link lines LL can be disposed in the non-display area NA. The plurality of link lines LL can be wirings that transmit various signals from one or more flexible circuit boards (or flexible films) 157 and the printed circuit boards 160 to the display area AA. The plurality of link lines LL can extend from the plurality of pad electrodes PE in the second non-display area NA2 toward the bending area BA and the first non-display area NA1 to be electrically connected to a plurality of driving lines VL in the display area AA. The plurality of pixel driving circuits PD can be driven by receiving signals from one or more flexible circuit boards (or flexible films) 157 and printed circuit boards 160 through the driving lines VL in the display area AA and the link lines LL in the non-display area NA.

For example, the plurality of driving lines VL can be wirings for transmitting signals output from the flexible circuit board (or flexible film) 157 and the printed circuit board 160 to the plurality of pixel driving circuits PD together with the plurality of link lines LL. The plurality of driving lines VL can be disposed in the display area AA to be electrically connected to each of the plurality of pixel driving circuits PD. The plurality of driving lines VL can extend from the display area AA toward the non-display area NA to be electrically connected to the plurality of link lines LL. Therefore, the signals output from the flexible circuit board (or flexible film) 157 and the printed circuit board 160 can be transmitted to each of the plurality of pixel driving circuits PD through the plurality of link lines LL and the plurality of driving lines VL.

When the bending area BA is bent, portions of the plurality of link lines LL can be also bent together. Stress can be concentrated on a portion of the bent link line LL, which can cause cracks to occur in the link line LL. So, the plurality of link lines LL can be made of a conductive material having excellent ductility to reduce the cracks when the bending area BA is bent. For example, the plurality of link lines LL can be configured with a conductive material having excellent ductility, such as gold (Au), silver (Ag), aluminum (Al) or the like. However, the example embodiments of the present disclosure are not limited thereto. Alternatively, the plurality of link lines LL can be configured with one of various conductive materials used in the display area AA. For example, the plurality of link lines LL can be configured with molybdenum (Mo), chromium (Cr), titanium (Ti), nickel (Ni), neodymium (Nd), copper (Cu), an alloy of silver (Ag) and magnesium (Mg), or any alloy thereof. However, the example embodiments of the present disclosure are not limited thereto. The plurality of link lines LL can be configured in a multilayer structure including various conductive materials. For example, the plurality of link lines LL can be configured in a triple layer structure of titanium (Ti)/aluminum (Al)/titanium (Ti). However, the example embodiments of the present disclosure are not limited thereto.

The plurality of link lines LL can be configured in various shapes to reduce the stress. At least a portion of the plurality of link lines LL disposed on the bending area BA can extend in the same direction as the extension direction of the bending area BA, or in a direction different from the extension direction of the bending area BA, to reduce the stress. For example, in a case where the bending area BA extends in one direction from the first non-display area NA1 toward the second non-display area NA2, at least a portion of the link line LL disposed on the bending area BA can extend in a direction inclined with respect to the one direction. In another example, at least a portion of the plurality of link lines LL can be configured in patterns of various shapes. For example, at least a portion of the plurality of link lines LL disposed on a bending area BA can have a shape in which a conductive pattern having at least one shape of a diamond shape, a rhombus shape, a trapezoidal wave shape, a triangular wave shape, a sawtooth wave shape, a sine wave shape, a circular shape, and an omega (Ω) shape can be repeatedly disposed. However, the example embodiments of the present disclosure are not limited thereto. Therefore, in order to minimize the stress concentrated on the plurality of link lines LL and the resulting cracks, the shape of the plurality of link lines LL can be formed in various shapes including the shapes described above. However, the example embodiments of the present disclosure are not limited thereto.

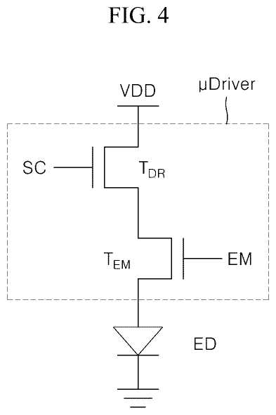

FIG. 4 is a diagram showing a circuit structure according to an example embodiment of the present disclosure.

In FIG. 4, one light-emitting element ED is, by way of example, connected to a micro driver μDriver. However, the example embodiments of the present disclosure are not limited thereto. For example, eight light-emitting elements (LEDs) can be connected to one micro driver. In another example, sixteen light-emitting elements ED can be connected to one micro driver, or thirty two light-emitting elements ED or sixty four light-emitting elements ED can be connected to one micro driver simultaneously. The light-emitting element ED can be a micro light-emitting element (micro LED).

Referring to FIG. 4, one micro driver can include at least one driving transistor T_{DR} and at least one light-emission transistor T_{EM}. However, example embodiments of the present disclosure are not limited thereto.

The at least one driving transistor T_{DR} and at least one light-emission transistor T_{EM} can be implemented as a thin film transistor (TFT).

Active layers of the thin-film transistors TFTs can be formed of a semiconductor material, such as an oxide semiconductor, amorphous semiconductor, or polycrystalline semiconductor, but is not limited thereto.

The oxide semiconductor material can have an excellent effect of preventing a leakage current and relatively inexpensive manufacturing cost. The oxide semiconductor can be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor can include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor can be made of polycrystalline silicon (poly-Si), but is not limited thereto.

The amorphous semiconductor material can be made of amorphous silicon (a-Si), but is not limited thereto.

For example, the driving transistor T_{DR} can have a first electrode to which a high-potential power supply voltage VDD is applied, a second electrode to which a first electrode of the light-emission transistor T_{EM} is connected, and a gate electrode to which a scan signal SC is applied. The scan signal SC applied to the gate electrode of the driving transistor T_{DR} can be a direct current (DC) power source, and a fixed reference voltage Vref can be applied every frame. However, the example embodiments of the present disclosure are not limited thereto.

The light-emission transistor T_{EM} can have the first electrode to which the second electrode of the driving transistor T_{D}R is connected, a second electrode to which the light-emitting element ED is connected, and a gate electrode to which a light-emission signal EM is applied. The light-emission signal EM applied to the gate electrode of the light-emission transistor T_{EM} can be a pulse width modulation (PWM) signal that varies every frame. However, the example embodiments of the present disclosure are not limited thereto.

The light-emitting element ED can have the first electrode connected to the second electrode of the light-emission transistor T_{EM}, and a second electrode connected to ground. For example, the first electrode can be an anode electrode, and the second electrode can be a cathode electrode. However, the example embodiments of the present disclosure are not limited thereto.

Each of the driving transistor T_{DR} and the light-emission transistor T_{EM} can be an n-type or a p-type transistor.

In the micro driver, the driving transistor T_{DR} can be turned on by the scan signal SC applied from the timing controller, and the light-emitting transistor T_{EM} can be turned on by the light-emitting signal EM. By this, a driving current can be applied to the light-emitting element ED via the driving transistor T_{DR} and the light-emitting transistor T_{EM} by the high-potential power supply voltage VDD applied to the first electrode of the driving transistor T_{DR}, thereby causing the light-emitting element ED to emit light.

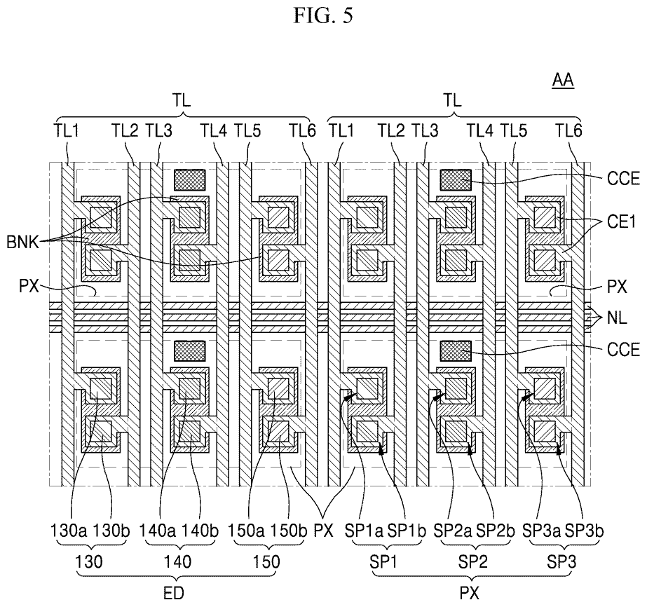

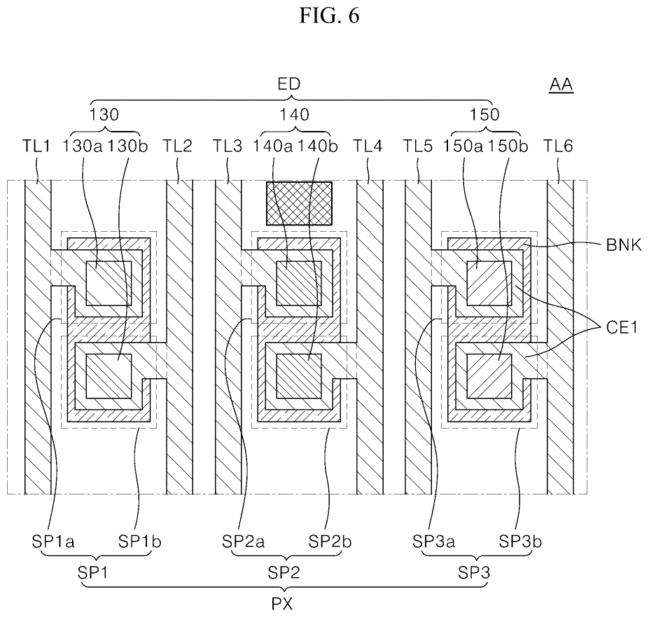

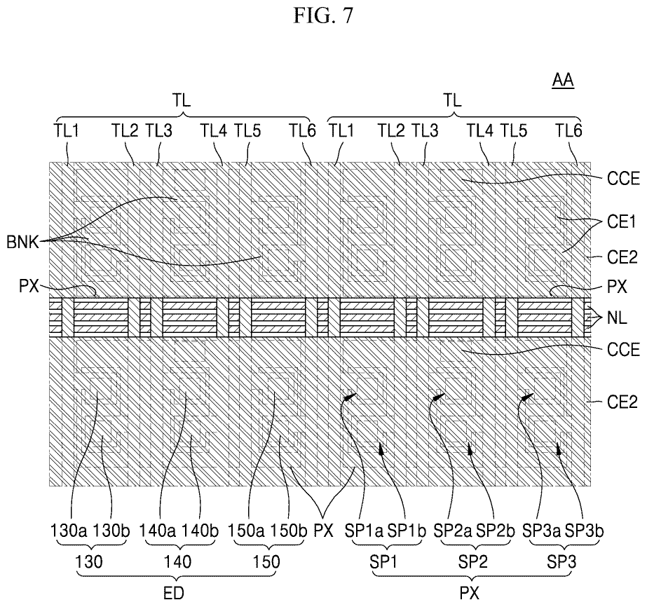

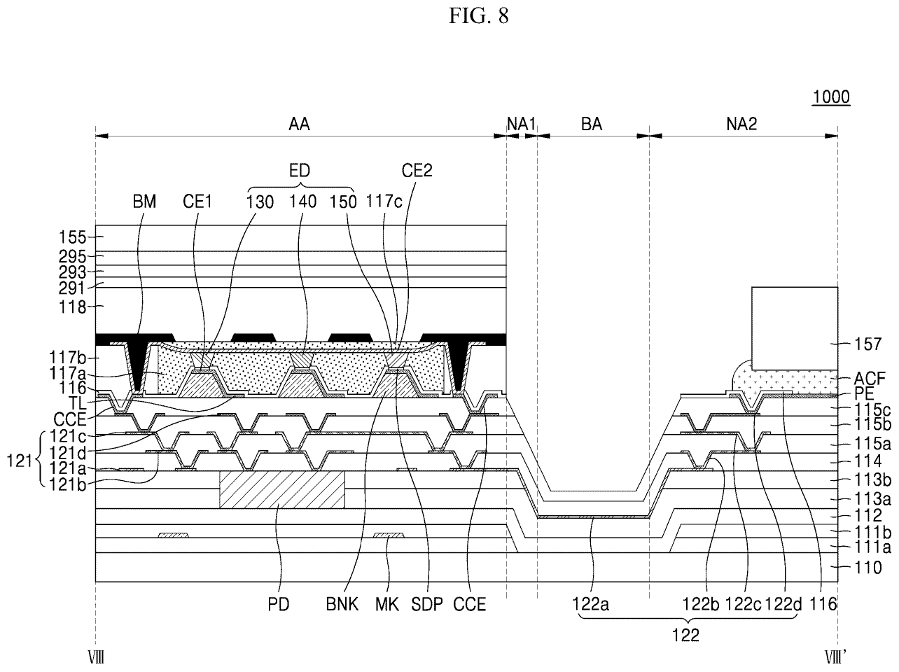

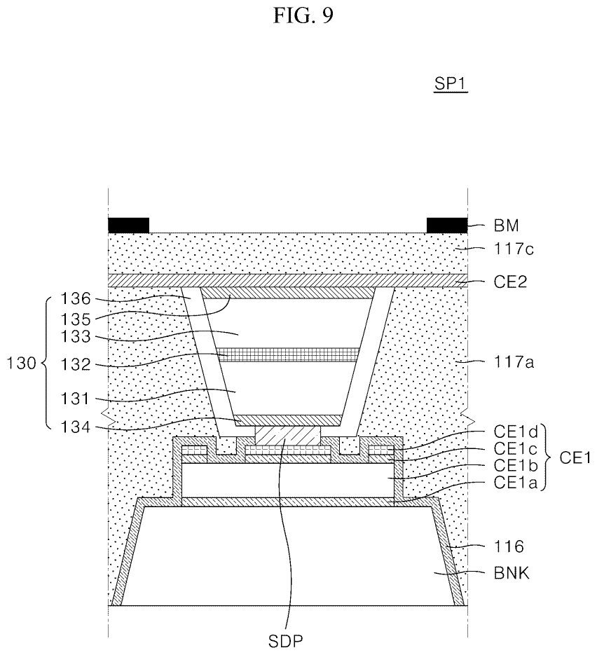

FIG. 5, FIG. 6 and FIG. 7 are plan views of a display device according to an example embodiment of the present disclosure. FIGS. 8 and 9 are cross-sectional views of a display device according to an example embodiment of the present disclosure.

For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels. For example, FIG. 8 is a cross-sectional view of the display area AA, the first non-display area NA, the bending area BA, and the second non-display area NA2. For example, FIG. 9 is a cross-sectional view of a display area including one sub-pixel SP1.

In FIGS. 5 and 6, only a plurality of signal lines TL, a plurality of communication lines NLs, a plurality of first electrodes CE1, a plurality of banks BNK, and a plurality of light-emitting elements ED are illustrated. However, the example embodiments of the present disclosure are not limited thereto. FIG. 7 is an enlarged plan view in which a plurality of second electrodes CE2 are additionally disposed to FIG. 5.

Referring to FIGS. 5, 6, and 9, a plurality of pixels PX configured with a plurality of sub-pixels can be disposed in the display area AA. Each of the plurality of sub-pixels can include a light-emitting element ED, and can independently emit light. The plurality of sub-pixels can be arranged in a plurality of rows and a plurality of columns and thus can be arranged in a matrix form. However, the example embodiments of the present disclosure are not limited thereto.

The plurality of sub-pixels can include a first sub-pixel SP1, a second sub-pixel SP2, and a third sub-pixel SP3. For example, one of the first sub-pixel SP1, the second sub-pixel SP2 and the third sub-pixel SP3 can be a red sub-pixel, another thereof can be a green sub-pixel, and the rest one thereof can be a blue sub-pixel. In some example embodiments, plurality of sub-pixels can further includes a fourth sub-pixel, and the fourth sub-pixel can be a white sub-pixel. The types of the plurality of sub-pixels are given only as an example, and the example embodiments of the present disclosure are not limited thereto.

For example, the plurality of subpixels of the pixel PX can be variously modified in colors and configurations, as necessary. For example, the plurality of subpixels can include red, green, and blue subpixels, in which the red, green, and blue subpixels can be disposed in a repeated manner. Alternatively, the plurality of subpixels can include red, green, blue, and white subpixels, in which the red, green, blue, and white subpixels can be disposed in a repeated manner, or the red, green, blue, and white subpixels can be disposed in a quad type. For example, the red sub pixel, the blue sub pixel, and the green sub pixel can be sequentially disposed along a row direction, or the red sub pixel, the blue sub pixel, the green sub pixel and the white sub pixel can be sequentially disposed along the row direction. However, in the embodiment of the present disclosure, the color type, disposition type, and disposition order of the subpixels are not limiting, and can be configured in various forms according to light-emitting characteristics, device lifespans, and device specifications.

Meanwhile, the subpixels can have different light-emitting areas according to light-emitting characteristics. For example, a subpixel that emits light of a color different from that of a blue subpixel can have a different light-emitting area from that of the blue subpixel. For example, the red subpixel, the blue subpixel, and the green subpixel, or the red subpixel, the blue subpixel, the white subpixel, and the green subpixel can each has a different light-emitting area.

Each of the plurality of pixels PX can include one or more first sub-pixels SP1, one or more second sub-pixels SP2, and one or more third sub-pixels SP3. For example, one pixel PX can include a pair of first sub-pixels SP1, a pair of second sub-pixels SP2, and a pair of third sub-pixels SP3. The pair of first sub-pixels SP1 can include a (1-1)-th sub-pixel SP1a and a (1-2)-th sub-pixel SP1b. The pair of second sub-pixels SP2 can include a (2-1)-th sub-pixel SP2a and a (2-2)-th sub-pixel SP2b. The pair of third sub-pixels SP3 can include a (3-1)-th sub-pixel SP3a and a (3-2)-th sub-pixel SP3b. For example, one pixel PX can include a (1-1)-th sub-pixel SP1a and a (1-2)-th sub-pixel SP1b, a (2-1)-th sub-pixel SP2a and a (2-2)-th sub-pixel SP2b, and a (3-1)-th sub-pixel SP3a and a (3-2)-th sub-pixel SP3b. However, example embodiments of the present disclosure are not limited thereto.

The plurality of sub-pixels constituting one pixel PX can be arranged in various ways. For example, in one pixel PX, the pair of first sub-pixels SP1 can be disposed in the same column, the pair of second sub-pixels SP2 can be disposed in the same column, and the pair of third sub-pixels SP3 can be disposed in the same column. The first sub-pixel SP1, the second sub-pixel SP2, and the third sub-pixel SP3 can be disposed in the same row. Alternatively, in one pixel PX, a pair of first sub-pixels SP1 can be arranged in the same row, a pair of second sub-pixels SP2 can be arranged in the same row, and a pair of third sub-pixels SP3 can be arranged in the same row. The first sub-pixel SP1, the second sub-pixel SP2, and the third sub-pixel SP3 can be arranged in the same column. The number and arrangement of the plurality of sub-pixels constituting one pixel PX are given only as an example, and the example embodiments of the present disclosure are not limited thereto.

The plurality of signal lines TL can be disposed in the area between a plurality of sub-pixels. The plurality of signal lines TL can extend in the column direction while being disposed between adjacent ones of the plurality of sub-pixels. The plurality of signal lines TL can be wirings that transmit the anode voltage from the pixel driving circuit PD to the plurality of sub-pixels. For example, the plurality of signal lines TL can be electrically connected to the plurality of pixel driving circuits PD and first electrodes CE1s of the plurality of sub-pixels. The anode voltage output from the pixel driving circuit PD can be transmitted to the first electrodes CE1s of the plurality of sub-pixels through the plurality of signal lines TL. For example, the first electrode CE1 can be an electrode electrically connected to an anode electrode 134 of the light-emitting element ED. By this, the anode voltage from the signal line TL can be transmitted to the anode electrode 134 of the light-emitting element ED through the first electrode CE1.

Therefore, instead of forming a plurality of transistors and storage capacitors in each of the plurality of sub-pixels, by using the pixel driving circuit PD in which a plurality of pixel circuits are integrated, the structure of the display device 1000 can be simplified. In addition, since the circuits disposed in each of the plurality of sub-pixels are integrated into one pixel driving circuit PD, high-efficiency and low-power driving can be realized.

The plurality of signal lines TL can include a first signal line TL1, a second signal line TL2, a third signal line TL3, a fourth signal line TL4, a fifth signal line TL5, and a sixth signal line TL6. Each of the first signal line TL1 and the second signal line TL2 can be electrically connected to the pair of first sub-pixels SP1. Each of the third signal line TL3 and the fourth signal line TL4 can be electrically connected to the pair of second sub-pixels SP2. Each of the fifth signal line TL5 and the sixth signal line TL6 can be electrically connected to the pair of third sub-pixels SP3.

The first signal line TL1 can be disposed at one side of the pair of first sub-pixels SP1, and the second signal line TL2 can be disposed at the other side of the pair of first sub-pixels SP1. The first signal line TL1 can be electrically connected to the first electrode CE1 of one of the first sub-pixels SP1 of the pair of first sub-pixels SP1, for example, the (1-1)-th sub-pixel SP1a. The second signal line TL2 can be electrically connected to the first electrode CE1 of the remaining first sub-pixel SP1 of the pair of first sub-pixels SP1, for example, the (1-2)-th sub-pixel SP1b.

The third signal line TL3 can be disposed at one side of the pair of second sub-pixels SP2, and the fourth signal line TL4 can be disposed at the other side of the pair of second sub-pixels SP2. For example, the third signal line TL3 can be disposed neighboring the second signal line TL2. The third signal line TL3 can be electrically connected to the first electrode CE1 of one of the second sub-pixels SP2 of the pair of second sub-pixels SP2, for example, the (2-1)-th sub-pixel SP2a. The fourth signal line TL4 can be electrically connected to the first electrode CE1 of the remaining second sub-pixel SP2 of the pair of second sub-pixels SP2, for example, the (2-2)-th sub-pixel SP2b.

The fifth signal line TL5 can be disposed at one side of the pair of third sub-pixels SP3, and the sixth signal line TL6 can be disposed at the other side of the pair of third sub-pixels SP3. For example, the fifth signal line TL5 can be disposed neighboring the fourth signal line TL4. The sixth signal line TL6 can be disposed neighboring the first signal line TL1 connected to the neighboring pixel PX. The fifth signal line TL5 can be electrically connected to the first electrode CE1 of one of the third sub-pixels SP3 of the pair of third sub-pixels SP3, for example, the (3-1)-th sub-pixel SP3a. The sixth signal line TL6 can be electrically connected to the first electrode CE1 of the remaining third sub-pixel SP3 of the pair of third sub-pixels SP3, for example, the (3-2)-th sub-pixel SP3b.

As shown in FIG. 5, a first pixel includes a pair of first sub-pixels SP1, a pair of second sub-pixels SP2, and a pair of third sub-pixels SP3, wherein, the pair of first sub-pixels SP1 includes a (1-1)-th sub-pixel SP1a and a (1-2)-th sub-pixel SP1b, the pair of second sub-pixels SP2 includes a (2-1)-th sub-pixel SP2a and a (2-2)-th sub-pixel SP2b, and the pair of third sub-pixels SP3 includes a (3-1)-th sub-pixel SP3a and a (3-2)-th sub-pixel SP3b. The first signal line TL1 can be electrically connected to the first electrode CE1 of the (1-1)-th sub-pixel SP1a, the second signal line TL2 can be electrically connected to the first electrode CE1 of the (1-2)-th sub-pixel SP1b, the third signal line TL3 can be electrically connected to the first electrode CE1 of the (2-1)-th sub-pixel SP2a, the fourth signal line TLA can be electrically connected to the first electrode CE1 of the (2-2)-th sub-pixel SP2b, the fifth signal line TL5 can be electrically connected to the first electrode CE1 of the (3-1)-th sub-pixel SP3a, and the sixth signal line TL6 can be electrically connected to the first electrode CE1 of the (3-2)-th sub-pixel SP3b. Meanwhile, the first signal line TL1 connected to the first pixel is adjacent to the sixth signal line TL6 connected to a second pixel adjacent to the first pixel. However, the present disclosure is not limited thereto.

The plurality of signal lines TL can be made of a conductive material. For example, the plurality of signal lines TL can be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like. However, the example embodiments of the present disclosure are not limited thereto. In another example, the plurality of signal lines TL can be formed of a multilayer structure of conductive material. For example, the plurality of signal lines TL can be configured in a multilayer structure of titanium (Ti)/aluminum (Al)/titanium (Ti)/indium tin oxide (ITO). However, the example embodiments of the present disclosure are not limited thereto.

The plurality of communication lines NLs can be disposed in an area between the plurality of pixels PX. The plurality of communication lines NLs can be disposed to extend in the row direction in the area between adjacent ones of the plurality of pixels PX. The plurality of communication lines NLs can be disposed in an area between adjacent ones of the plurality of second electrodes CE2s, and may not overlap with the plurality of second electrodes CE2s. For example, the plurality of communication lines NL can be wirings used for short-range communication such as Near Field Communication (NFC). The plurality of communication lines NL can function as antennas. For example, the plurality of communication lines NL can be a plurality of connection lines or the like. However, the example embodiments of the present disclosure are not limited thereto.

According to the present disclosure, the bank BNK can be disposed in each of the plurality of sub-pixels. The bank BNK can be formed of an opaque material (for example, black) in order to prevent light interference between adjacent pixels. In this case, the bank BNK can include a light shielding material constituted by at least one of a color pigment, organic black, or carbon, without being limited thereto.

For example, the bank BNK can be formed of an organic layer such as an acryl-based material, an epoxy-based material, a phenolic-based material, a polyamide-based material, or a polyimide-based material. Meanwhile, the bank BNK can include an inorganic insulating material, such as silicon nitride (SiNx) or silicon oxide (SiOx), or the bank BNK can be formed of black resin. However, the present disclosure is not limited thereto.

A plurality of banks BNK can be structures on which a plurality of light-emitting elements ED are mounted. The plurality of banks BNK can guide the positions of the plurality of light-emitting elements ED in a transfer process of transferring the plurality of light-emitting elements ED to the display device 1000. In a transfer process of a plurality of light-emitting elements ED, a plurality of light-emitting elements ED can be transferred onto a plurality of banks BNK. The plurality of banks BNK can be bank patterns or bank structures. However, the example embodiments of the present disclosure are not limited thereto.

The bank BNK of the first sub-pixel SP1, the bank BNK of the second sub-pixel SP2, and the bank BNK of the third sub-pixel SP3 can be disposed spaced apart from each other. The bank BNK of the first sub-pixel SP1, the bank BNK of the second sub-pixel SP2, and the bank BNK of the third sub-pixel SP3 can be configured to be separated from each other. Accordingly, the banks BNK of the first sub-pixel SP1, the second sub-pixel SP2, and the third sub-pixel SP3 to which different types of light-emitting elements ED are transferred can be easily identified.

The bank BNK of the (1-1)-th sub-pixel SP1a and the bank BNK of the (1-2)-th sub-pixel SP1b can be connected to each other, or can be formed to be spaced apart or separated from each other. For example, depending on the consideration of design requirements and the like of the transfer process, the bank BNK of the (1-1)-th sub-pixel SP1a and the bank BNK of the (1-2)-th sub-pixel SP1b in which the light-emitting elements ED of the same type are disposed can be connected to each other, or can be spaced apart or separated from each other. Further, the bank BNK of the (2-1)-th sub-pixel SP2a and the bank BNK of the (2-2)-th sub-pixel SP2b can be connected to each other, or can be formed to be spaced apart or separated from each other. The bank BNK of the (3-1)-th sub-pixel SP3a and the bank BNK of the (3-2)-th sub-pixel SP3b can be connected to each other, or can be formed to be spaced apart or separated from each other. Accordingly, the banks BNK of the pair of first sub-pixels SP1, the banks BNK of the pair of second sub-pixels SP2, and the banks BNK of the pair of third sub-pixels SP3 can be formed in various ways, and so the example embodiments of the present disclosure are not limited thereto.

For example, the plurality of banks BNK can be made of an organic insulating material. The plurality of banks BNK can be configured in a single-layer or multi-layer structure of organic insulating material. For example, the plurality of banks BNK can be made of a photoresist, polyimide (PI), or acrylic-based material, or the like. However, the example embodiments of the present disclosure are not limited thereto.

The first electrode CE1 can be disposed on each of the plurality of sub-pixels. The first electrode CE1 can be disposed on the bank BNK. The first electrode CE1 can be electrically connected to one of the plurality of signal lines TL. At least a portion of the first electrode CE1 can extend outside of the bank BNK to be electrically connected to a signal line TL closest to the first electrode CE1. For example, a portion of the first electrode CE1 of the (1-1)-th sub-pixel SP1a can extend to one side area of the (1-1)-th sub-pixel SP1a to be electrically connected to the first signal line TL1, and a portion of the first electrode CE1 of the (1-2)-th sub-pixel SP1b can extend to the other side area of the (1-2)-th sub-pixel SP1b to be electrically connected to the second signal line TL2. A portion of the first electrode CE1 of the (2-1)-th sub-pixel SP2a can extend to one side area of the (2-1)-th sub-pixel SP2a to be electrically connected to the third signal line TL3, and a portion of the first electrode CE1 of the (2-2)-th sub-pixel SP2b can extend to the other side area of the (2-2)-th sub-pixel SP2b to be electrically connected to the fourth signal line TL4. A portion of the first electrode CE1 of the (3-1)-th sub-pixel SP3a can extend to one side area of the (3-1)-th sub-pixel SP3a to be electrically connected to the fifth signal line TL5, and a portion of the first electrode CE1 of the (3-2)-th sub-pixel SP3b can extend to the other side area of the (3-2)-th sub-pixel SP3b to be electrically connected to the sixth signal line TL6. However, example embodiments of the present disclosure are not limited thereto.

The first electrode CE1 can be electrically connected to the anode electrode 134 of the light-emitting element ED to transmit the anode voltage from the pixel driving circuit PD to the light-emitting element ED through the signal line TL. To the first electrode CE1 of each of the plurality of sub-pixels, a different voltage can be applied depending on the image to be displayed. For example, a different voltage can be applied to the first electrode CE1 of each of the plurality of sub-pixels. The first electrode CE1 can be a pixel electrode, and the example embodiments of the present disclosure are not limited thereto.

The first electrode CE1 can be made of a conductive material. For example, the first electrode CE1 can be configured as one body with a plurality of signal lines TL. For example, the first electrode CE1 can be made of the same conductive material as the plurality of signal lines TL. However, the example embodiments of the present disclosure are not limited thereto. For example, the first electrode CE1 can be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), or the like. However, the example embodiments of the present disclosure are not limited thereto. In another example, the first electrode CE1 can be configured in a multilayer structure of conductive material. For example, the plurality of first electrode CE1 can be configured in a multilayer structure of titanium (Ti)/aluminum (Al)/titanium (Ti)/indium tin oxide (ITO). However, the example embodiments of the present disclosure are not limited thereto.

The light-emitting element ED can be disposed in each of the plurality of sub-pixels. The plurality of light-emitting elements ED can be any one of a light-emitting diode (LED) and a micro light-emitting diode (Micro LED). However, the example embodiments of the present disclosure are not limited thereto. The plurality of light-emitting elements ED can be disposed on the bank BNK and the first electrode CE1. Each of the plurality of light-emitting elements ED can be disposed on the first electrode CE1 to be electrically connected to the first electrode CE1. Therefore, the light-emitting element ED can emit light by receiving an anode voltage from the pixel driving circuit PD through the signal line TL and the first electrode CE1.

Each of the plurality of light-emitting elements ED can include a first light-emitting element 130, a second light-emitting element 140, and a third light-emitting element 150. The first light-emitting element 130 can be disposed in the first sub-pixel SP1. The second light-emitting element 140 can be disposed in the second sub-pixel SP2. The third light-emitting element 150 can be disposed in the third sub-pixel SP3. For example, one of the first light-emitting element 130, the second light-emitting element 140, and the third light-emitting element 150 can be a red light-emitting element, another thereof can be a green light-emitting element, and the rest one thereof can be blue light-emitting elements. For example, the first light-emitting element 130 is a red light-emitting element, the second light-emitting element 140 is a green light-emitting element, and the third light-emitting element 150 is a blue light-emitting element. However, the example embodiments of the present disclosure are not limited thereto. Accordingly, by combining red light, green light, and blue light emitted from the plurality of light-emitting elements ED, light of various colors, including white, can be implemented. The types of the plurality of light-emitting elements ED are given only as an example, and the example embodiments of the present disclosure are not limited thereto.

The first light-emitting element 130 can include a (1-1)-th light-emitting element 130a disposed in the (1-1)-th sub-pixel SP1a and a (1-2)-th light-emitting element 130b disposed in the (1-2)-th sub-pixel SP1b. The second light-emitting element 140 can include a (2-1)-th light-emitting element 140a disposed in the (2-1)-th sub-pixel SP2a and a (2-2)-th light-emitting element 140b disposed in the (2-2)-th sub-pixel SP2b. The third light-emitting element 150 can include a (3-1)-th light-emitting element 150a disposed in the (3-1)-th sub-pixel SP3a and a (3-2)-th light-emitting element 150b disposed in the (3-2)-th sub-pixel SP3b.

Referring to FIGS. 5, 6, 7, and 9 together, the second electrode CE2 can be disposed on each of the plurality of sub-pixels. The second electrode CE2 can be disposed on the light-emitting element ED. The second electrode CE2 can be electrically connected to the pixel driving circuit PD through a plurality of contact electrodes CCE.

For example, the second electrode CE2 can be electrically connected to the cathode electrode 135 of the light-emitting element ED to transmit the cathode voltage from the pixel driving circuit PD to the light-emitting element ED. The same cathode voltage can be applied to the second electrode CE2 of each of the plurality of sub-pixels. For example, the same voltage can be applied to the second electrode CE2 of each of the plurality of sub-pixels and the cathode electrode 135 of the light-emitting element ED. The second electrode CE2 can be a common electrode. However, the example embodiments of the present disclosure are not limited thereto.

At least some of the plurality of sub-pixels can share the second electrode CE2 with each other. At least some of the second electrodes CE2 of the plurality of respective sub-pixels can be electrically connected to each other. As the same voltage is applied to the second electrodes CE2, the second electrode CE2 can be shared to be used for at least some sub-pixels. For example, the second electrodes CE2 of at least some of the pixels PX among the plurality of pixels PX disposed in the same row can be connected to each other. For example, one second electrode CE2 can be disposed on a plurality of pixels PX. For example, one second electrode CE2 can be disposed for every n sub-pixels.

For example, some of the second electrodes CE2 of the plurality of respective sub-pixels can be disposed to be spaced apart from or separated from each other. For example, the second electrode CE2 connected to the pixels PX of the n-th row and the second electrode CE2 connected to the pixels PX of the (n+1)-th row can be disposed to be spaced apart from each other or separated from each other. For example, the plurality of second electrodes CE2 can be disposed to be spaced apart from each other with a plurality of communication lines NL interposed and extending therebetween in the row direction. Thus, the number of the plurality of sub-pixels can be greater than the number of the plurality of second electrodes CE2. In another example, all of the second electrodes CE2 of a plurality of sub-pixels can be connected to each other so that only one second electrode CE2 is placed on the substrate 110. However, the example embodiments of the present disclosure are not limited thereto.

The plurality of second electrodes CE2 can be made of a transparent conductive material. However, the example embodiments of the present disclosure are not limited thereto. The plurality of second electrodes CE2 can be made of a transparent conductive material, so that light emitted from the light-emitting element ED can be directed upward beyond the second electrodes CE2. For example, the second electrode CE2 can be made of a transparent conductive material such as indium tin oxide (ITO), indium zinc oxide (IZO), indium gallium zinc oxide (IGZO), or the like. However, the example embodiments of the present disclosure are not limited thereto. The second electrode CE2 can be a transparent electrode.

The plurality of contact electrodes CCE can be disposed on the substrate 110. For example, the plurality of contact electrodes CCE can be disposed to be spaced apart from the plurality of banks BNK and the plurality of signal lines TL. Each of the plurality of second electrodes CE2 can overlap with at least one contact electrode CCE. For example, one second electrode CE2 can overlap with the plurality of contact electrodes CCE.

For example, a plurality of contact electrodes CCE can be electrically connected to a plurality of second electrodes CE2. The plurality of contact electrodes CCE can be disposed between the substrate 110 and the plurality of second electrodes CE2 to transmit the cathode voltage from the pixel driving circuit PD to the second electrodes CE2.

For example, in a case where a micro LED is used as the light-emitting element ED, a plurality of micro LEDs can be formed on a wafer, and the micro LEDs can be transferred to the substrate 110 of the display device 1000 to manufacture the display device 1000. In the process of transferring a plurality of light-emitting elements ED having a microscopic size from the wafer to the substrate 110, various defects can be formed. For example, in some sub-pixels, a non-transfer defect can occur in which the light-emitting element ED is not transferred, and in other some sub-pixels, a defect can occur in which the light-emitting element ED is transferred outside the predetermined position due to an alignment error. Additionally, although the transfer process has been performed normally, the transferred light-emitting element ED itself can be defective. Therefore, taking into account the defects produced during the transfer process of the plurality of light-emitting elements ED, a plurality of light-emitting elements ED of the same type can be transferred to one sub-pixel. Lighting tests can be performed on the plurality of light-emitting elements ED, and only one light-emitting element ED that is ultimately judged to be normal can be used.

For example, the (1-1)-th light-emitting element 130a and the (1-2)-th light-emitting element 130b can be transferred together to one pixel PX, and can be tested to find whether they are defective or not. If both the (1-1)-th light-emitting element 130a and the (1-2)-th light-emitting element 130b are determined to be normal, only the (1-1)-th light-emitting element 130a can be used, and the (1-2)-th light-emitting element 130b may not be used. In another example, if only the (1-2)-th light-emitting element 130b among the (1-1)-th light-emitting element 130a and the (1-2)-th light-emitting element 130b is judged to be normal, the (1-1)-th light-emitting element 130a may not be used and only the (1-2)-th light-emitting element 130b can be used. Therefore, even if a plurality of light-emitting elements ED of the same type are transferred to one pixel PX, only one light-emitting element ED can be used ultimately.

Accordingly, one of the pair of light-emitting elements ED can be a main or primary light-emitting element ED, and the other light-emitting element ED thereof can be a redundant light-emitting element ED. The redundant light-emitting element ED can be a spare light-emitting element ED that has been transferred to prepare for failure of the main light-emitting element ED. In case of the failure of the main light-emitting element ED, the redundant light-emitting element ED can be used as a replacement for it. Therefore, by transferring the main light-emitting element ED and the redundant light-emitting element ED together to one pixel PX, the deterioration of display quality due to defects in light-emitting element ED itself can be minimized.

For example, the (1-1)-th light-emitting element 130a, the (2-1)-th light-emitting element 140a, and the (3-1)-th light-emitting element 150a transferred to one pixel PX can be used as main light-emitting elements ED, while the (1-2)-th light-emitting element 130b, the (2-2)-th light-emitting element 140b, and the (3-2)-th light-emitting element 150b can be used as redundant light-emitting elements ED.

FIG. 8 is a cross-sectional view of a display device according to an example embodiment of the present disclosure. FIG. 9 is a cross-sectional view of a display device according to an example embodiment of the present disclosure. For example, FIG. 8 is a cross-sectional view of the display area AA, the first non-display area NA1, the bending area BA, and the second non-display area NA2. For example, FIG. 9 is a cross-sectional view of a display area including one sub-pixel SP1.

Referring to FIG. 8, in the remaining area of the substrate 110 except the bending area BA a first buffer layer 111a and a second buffer layer 111b can be disposed.

The first buffer layer 111a and the second buffer layer 111b can be disposed in the display area AA, the first non-display area NA1, and the second non-display area NA2. The first buffer layer 111a and the second buffer layer 111b can reduce the penetration of moisture or impurities through the substrate 110. The first buffer layer 111a and the second buffer layer 111b can be made of an inorganic insulating material. For example, the first buffer layer 111a and the second buffer layer 111b can be configured in a single-layer or multi-layer structure of silicon oxide (SiOx) or silicon nitride (SiNx). For example, the first buffer layer 111a and the second buffer layer 111b can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si), but the example embodiments of the present disclosure are not limited thereto. The first buffer layer 111a and the second buffer layer 111b can be excluded in accordance with the structure or properties of the display device. However, the example embodiments of the present disclosure are not limited thereto.

For example, a portion of the first buffer layer 111a and the second buffer layer 111b in the bending area BA can be removed. The upper surface of the substrate 110 located in the bending area BA can be exposed from the first buffer layer 111a and the second buffer layer 111b. By removing the first buffer layer 111a and the second buffer layer 111b made of an inorganic insulating material from the bending area BA, it is possible to minimize the cracks that can be produced in the first buffer layer 111a and the second buffer layer 111b when being bent.

Between the first buffer layer 111a and the second buffer layer 111b a plurality of alignment keys MK can be disposed. The plurality of alignment keys MK can be configured to identify the position of the pixel driving circuit PD during the manufacturing process of the display device 1000. For example, the plurality of alignment keys MK can be configured to align the position of the pixel driving circuit PD transferred on an adhesive layer 112. In another example, the plurality of alignment keys MK can be omitted.

The adhesive layer 112 can be disposed on the second buffer layer 111b. The adhesive layer 112 can be disposed in the display area AA, the first non-display area NA1, the bending area BA, and the second non-display area NA2. In another example, at least a portion of the adhesive layer 112 can be removed from the non-display area NA including the bending area BA. For example, the adhesive layer 112 can be made of any one of an adhesive polymer, an epoxy resin, a UV-curable resin, a polyimide resin, an acrylate resin, a urethane resin, and polydimethylsiloxane (PDMS). However, the example embodiments of the present disclosure are not limited thereto.

The pixel driving circuit PD can be disposed on the adhesive layer 112 in the display area AA. In a case where the pixel driving circuit PD is implemented with a driving chip (hereinafter, the pixel driving circuit PD can also be referred to as the driving chip PD), the driving chip can be mounted on the adhesive layer 112 by a transfer process. However, the example embodiments of the present disclosure are not limited thereto.

A first planarization layer 113a and a second planarization layer 113b can be disposed on the adhesive layer 112. The first planarization layer 113a and the second planarization layer 113b can be disposed to surround the side surface of the pixel driving circuit PD. However, the example embodiments of the present disclosure are not limited thereto. For example, the second planarization layer 113b can be disposed to cover at least a portion of the upper surface of the pixel driving circuit PD. For example, at least one of the first planarization layer 113a and the second planarization layer 113b disposed on the bending area BA can be omitted. For example, the first planarization layer 113a can be disposed entirely in the display area AA and the non-display area NA, and the second planarization layer 113b can be disposed in part in the display area AA, the first non-display area NA1, and the second non-display area NA2. For example, a portion of the second planarization layer 113b in the bending area BA can be removed. However, the example embodiments of the present disclosure are not limited thereto.

The first planarization layer 113a and the second planarization layer 113b can be made of an organic insulating material. However, the example embodiments of the present disclosure are not limited thereto. For example, the first planarization layer 113a and the second planarization layer 113b can be made of a photoresist, polyimide (PI), or photo acryl-based material, or the like. However, the example embodiments of the present disclosure are not limited thereto. For example, the first planarization layer 113a and the second planarization layer 113b can be an overcoat layer or an insulating layer. However, the example embodiments of the present disclosure are not limited thereto.

According to the present disclosure, a plurality of first connection lines 121 can be disposed on the second planarization layer 113b in the display area AA. The plurality of first connection lines 121 can be wirings for electrically connecting the pixel driving circuit PD with another component. For example, a pixel driving circuit PD can be electrically connected to the plurality of signal lines TL, the plurality of contact electrodes CCE and the like through the plurality of first connection lines 121. For example, the plurality of first connection lines 121 can include a (1-1)-th connection line 121a, a (1-2)-th connection line 121b, a (1-3)-th connection line 121c, and a (1-4)-th connection line 121d. However, the example embodiments of the present disclosure are not limited thereto.

For example, a plurality of (1-1)-th connection lines 121a can be disposed on the second planarization layer 113b. The plurality of (1-1)-th connection lines 121a can be electrically connected to the pixel driving circuit PD. The plurality of (1-1)-th connection lines 121a can transmit a voltage output from the pixel driving circuit PD to the first electrode CE1 or the second electrode CE2.

For example, a third planarization layer 114 can be disposed on the second planarization layer 113b. The third planarization layer 114 can be disposed entirely in the display area AA and the non-display area NA. In the bending area BA, the third planarization layer 114 can cover the side surface of the second planarization layer 113b and the upper surface of the first planarization layer 113a. The third planarization layer 114 can be made of an organic insulating material. For example, the third planarization layer 114 can be made of a photoresist, polyimide (PI), or photo acryl-based material, or the like. However, the example embodiments of the present disclosure are not limited thereto. For example, the first planarization layer 113a, the second planarization layer 113b, and the third planarization layer 114 can be made of the same material. However, the example embodiments of the present disclosure are not limited thereto.

A plurality of (1-2)-th connection lines 121b can be disposed on the third planarization layer 114. The plurality of (1-2)-th connection lines 121b can be connected to or directly connected to the pixel driving circuit PD. For example, a portion of the (1-2)-th connection line 121b can be directly connected to the pixel driving circuit PD through the contact hole in the third planarization layer 114. Another portion of the (1-2)-th connection line 121b can be electrically connected to the (1-1)-th connection line 121a through the contact hole in the third planarization layer 114. However, the example embodiments of the present disclosure are not limited thereto. The voltage output from the pixel driving circuit PD can be transmitted to the first electrode CE1 or the second electrode CE2 through a connection line different from the plurality of (1-2)-th connection lines 121b.

A first insulating layer 115a can be disposed on the plurality of (1-2)-th connection lines 121b. The first insulating layer 115a can be disposed entirely in the display area AA and the non-display area NA. However, the example embodiments of the present disclosure are not limited thereto. The first insulating layer 115a can be made of an organic insulating material. However, the example embodiments of the present disclosure are not limited thereto. For example, the first insulating layer 115a can be made of a photoresist, polyimide (PI), or photo acryl-based material, or the like. However, the example embodiments of the present disclosure are not limited thereto.

A plurality of (1-3)-th connection lines 121c can be disposed on the first insulating layer 115a. The plurality of (1-3)-th connection lines 121c can be electrically connected to the plurality of (1-2)-th connection lines 121b. For example, the (1-3)-th connection line 121c can be electrically connected to the (1-2)-th connection line 121b through the contact hole in the first insulating layer 115a.

A second insulating layer 115b can be disposed on the plurality of (1-3)-th connection lines 121c. The second insulating layer 115b can be disposed in the remaining area except the bending area BA. However, the example embodiments of the present disclosure are not limited thereto. The second insulating layer 115b can be disposed in the display area AA, the first non-display area NA1, and the second non-display area NA2. However, the example embodiments of the present disclosure are not limited thereto. For example, a portion of the second insulating layer 115b disposed in the bending area BA can be removed. The second insulating layer 115b can be made of an organic insulating material. However, the example embodiments of the present disclosure are not limited thereto. For example, the second insulating layer 115b can be made of a photoresist, polyimide (PI), or photo acryl-based material, or the like. However, the example embodiments of the present disclosure are not limited thereto.

A plurality of (1-4)-th connection lines 121d can be disposed on the second insulating layer 115b. The plurality of (1-4)-th connection lines 121d can be electrically connected to the plurality of (1-3)-th connection lines 121c. For example, the (1-4)-th connection line 121d can be electrically connected to the (1-3)-th connection line 121c through the contact hole in the second insulating layer 115b.

According to the present disclosure, a plurality of second connection lines 122 can be disposed on the second planarization layer 113b in the non-display area NA. The plurality of second connection lines 122 can be wirings for transmitting, to the pixel driving circuit PD in the display area AA, signals transmitted from the flexible circuit board (or flexible film) 157 and the printed circuit board 160 (see FIG. 1) to the pad part PAD. For example, the plurality of second connection lines 122 can be electrically connected to the plurality of pad electrodes PE to receive signals from the flexible circuit board (or flexible film) 157 and the printed circuit board 160.

For example, the plurality of second connection lines 122 can extend from the pad part PAD toward the display area AA to transmit signals to the wirings of the display area AA. In this case, the plurality of second connection lines 122 can function as the link lines LL. The plurality of second connection lines 122 can include a (2-1)-th connection line 122a, a (2-2)-th connection line 122b, a (2-3)-th connection line 122c, and a (2-4)-th connection line 122d.

A plurality of (2-1)-th connection lines 122a can be disposed on the second planarization layer 113b. The plurality of (2-1)-th connection lines 122a can extend from the second non-display area NA2 to the bending area BA and the first non-display area NA1. The plurality of (2-1)-th connection lines 122a can transmit, to the pixel driving circuit PD of the display area AA, signals transmitted from the flexible circuit board (or flexible film) 157 and the printed circuit board 160 to the pad part PAD.

A plurality of (2-2)-th connection lines 122b can be disposed on the third planarization layer 114. The plurality of (2-2)-th connection lines 122b can be disposed in the second non-display area NA2. The (2-2)-th connection line 122b can be electrically connected to the (2-1)-th connection line 122a through the contact hole in the third planarization layer 114. Accordingly, signals from the flexible circuit board (or flexible film) 157 and the printed circuit board can be transmitted to the (2-1)-th connection line 122a through the (2-2)-th connection line 122b.

The (2-3)-th connection line 122c can be disposed on the first insulating layer 115a. The (2-3)-th connection line 122c can be disposed in the second non-display area NA2. The (2-3)-th connection line 122c can be electrically connected to the (2-2)-th connection line 122b through the contact hole in the first insulating layer 115a. Accordingly, signals from the flexible circuit board (or flexible film) 157 and the printed circuit board 160 can be transmitted to the (2-1)-th connection line 122a through the (2-3)-th connection line 122c and the (2-2)-th connection line 122b.

The (2-4)-th connection line 122d can be disposed on the second insulating layer 115b. The (2-4)-th connection line 122d can be disposed in the second non-display area NA2. The (2-4)-th connection line 122d can be electrically connected to the (2-3)-th connection line 122c through the contact hole in the second insulating layer 115b. Accordingly, signals from the flexible film (157) and the printed circuit board 160 can be transmitted to the (2-1)-th connection line 122a through the (2-4)-th connection line 122d, the 2-3 connection line 122c and the (2-2)-th connection line 122b.

The plurality of first connection lines 121 and the plurality of second connection lines 122 can be made of any one of various conductive materials used in the display area AA or a conductive material having excellent ductility. For example, the second connection line 122 whose portion is disposed in the bending area can be made of a conductive material having excellent ductility, such as gold (Au), silver (Ag), aluminum (Al) or the like. However, the example embodiments of the present disclosure are not limited thereto. In another example, the plurality of first connection line 121 and the plurality of second connection line 122 can be made of molybdenum (Mo), chromium (Cr), titanium (Ti), nickel (Ni), neodymium (Nd), copper (Cu), an alloy of silver (Ag) and magnesium (Mg), or any alloy thereof. However, the example embodiments of the present disclosure are not limited thereto.

The third insulating layer 115c can be disposed on a plurality of first connection lines 121 and a plurality of second connection lines 122. The third insulating layer 115c can be disposed in the remaining area except the bending area BA. However, the example embodiments of the present disclosure are not limited thereto. The third insulating layer 115c can be disposed in the display area AA, the first non-display area NA1, and the second non-display area NA2. A portion of the third insulating layer 115c in the bending area BA can be removed. The third insulating layer 115c can be made of an organic insulating material. However, the example embodiments of the present disclosure are not limited thereto. For example, the third insulating layer 115c can be made of a photoresist, polyimide (PI), or photo acryl-based material, or the like. However, the example embodiments of the present disclosure are not limited thereto.

A plurality of banks BNK can be disposed on the third insulating layer 115c in the display area AA. The plurality of banks BNK can be disposed to overlap with the plurality of sub-pixels respectively. On the upper side of each of the plurality of banks BNK one or more light-emitting elements ED of the same kind can be disposed. The band BNK can be configured with an organic insulating material. However, the example embodiments of the present disclosure are not limited thereto. For example, the bank BNK can be made of a photoresist, polyimide (PI), or photo acryl-based material, or the like. However, the example embodiments of the present disclosure are not limited thereto.

A plurality of signal lines TL can be disposed on the third insulating layer 115c in the display area AA. The plurality of signal lines TL can be disposed in the area between the plurality of banks BNK. For example, the plurality of signal lines TL can be disposed adjacent to any one of the plurality of banks BNK.

A plurality of contact electrodes CCE can be disposed on the third insulating layer 115c in the display area AA. The plurality of contact electrodes CCE can supply the cathode voltage from the pixel driving circuit PD to the second electrode CE2.

The first electrode CE1 can be disposed on the bank BNK. For example, the first electrode CE1 can be disposed to extend from the adjacent signal line TL toward the upper surface of the bank BNK. The first electrode CE1 can be disposed on the upper surface of the bank BNK and on the side surface of the bank BNK. For example, the first electrode CE1 can be disposed to extend from the signal line TL on the upper surface of the third insulating layer 115c to the side surface of the bank BNK and the upper surface of the bank BNK.

Referring to FIG. 9, the first electrode CE1 can be made of a plurality of conductive layers. For example, the first electrode CE1 can include a first conductive layer CE1a, a second conductive layer CE1b, a third conductive layer CE1c, and a fourth conductive layer CE1d. However, the example embodiments of the present disclosure are not limited thereto.

The first conductive layer CE1a can be disposed on the bank BNK. The second conductive layer CE1b can be disposed on the first conductive layer CE1a. The third conductive layer CE1c can be disposed on the second conductive layer CE1b. The fourth conductive layer CE1d can be disposed on the third conductive layer CE1c. For example, each of the first conductive layer CE1a, the second conductive layer CE1b, the third conductive layer CE1c, and the fourth conductive layer CE1d can be made of titanium (Ti), molybdenum (Mo), aluminum (Al), or indium tin oxide (ITO). However, the example embodiments of the present disclosure are not limited thereto.

According to the present disclosure, some of the conductive layers having good reflection efficiency among the plurality of conductive layers constituting the first electrode CE1 can act as an alignment key for aligning the light-emitting element ED and/or a reflecting plate. For example, the second conductive layer CE1b among the plurality of conductive layers of the first electrode CE1 can include a reflective material. For example, the second conductive layer CE1b can include aluminum (Al). However, example embodiments of the present disclosure are not limited thereto. Accordingly, the second conductive layer CE1b can act as the reflecting plate. In addition, due to the high reflection efficiency of the second conductive layer CE1b, it can be easily identified during the manufacturing process, and thus the position or transfer position of the light-emitting element ED can be aligned based on the second conductive layer CE1b.

For example, in order to form the second conductive layer CE1b as the reflecting plate, the third conductive layer CE1c and the fourth conductive layer CE1d covering the second conductive layer CE1b can be partially removed or etched. For example, a portion of the third conductive layer CE1c and the fourth conductive layer CE1d disposed on the bank BNK can be removed or etched to expose the upper surface of the second conductive layer CE1b. For example, the central portion and the border portion or edge portion of the third conductive layer CE1c and the fourth conductive layer CE1d can be left, and the remaining portion can be removed, wherein the solder pattern SDP is placed on the central portion. For example, the border portion or edge portion of each of the third conductive layer CE1c made of titanium (Ti) and the fourth conductive layer CE1d made of indium tin oxide (ITO) may not be etched. Accordingly, it is possible to prevent other conductive layers of the first electrode CE1 from being corroded by the tetramethylammonium hydroxide (TMAH) solution used in the mask process of the first electrode CE1.

According to the present disclosure, the first conductive layer CE1a and the third conductive layer CE1c can include titanium (Ti) or molybdenum (Mo). The second conductive layer CE1b can include aluminum (Al). The fourth conductive layer CE1d can include a transparent conductive oxide layer, such as indium tin oxide (ITO) or indium zinc oxide (IZO), which has good adhesion to the solder pattern SDP and has corrosion resistance and acid resistance. However, the example embodiments of the present disclosure are not limited thereto.

The first conductive layer CE1a, the second conductive layer CE1b, the third conductive layer CE1c, and the fourth conductive layer CE1d can be sequentially deposited and then patterned by performing a photolithography process and an etching process. However, the example embodiments of the present disclosure are not limited thereto.

According to the present disclosure, the signal line TL, the contact electrode CCE, and the pad electrode PE disposed on the same layer as the first electrode CE1 can be configured in a multi-layer structure of conductive materials. However, the example embodiments of the present disclosure are not limited thereto. For example, the signal line TL, contact electrode CCE, and pad electrode PE can be formed in a multi-layer structure of indium tin oxide (ITO)/titanium (Ti)/aluminum (Al)/titanium (Ti). However, the example embodiments of the present disclosure are not limited thereto.

According to the present disclosure, the solder pattern SDP can be disposed on the first electrode CE1 in each of the plurality of sub-pixels. A solder pattern SDP can bond the light-emitting element ED to the first electrode CE1. The first electrode CE1 and the light-emitting element ED can be electrically connected through eutectic bonding using the solder pattern SDP. However, the example embodiments of the present disclosure are not limited thereto. For example, in a case where the solder pattern SDP is made of indium (In) and the anode electrode 134 of the light-emitting element ED is made of gold (Au), the solder pattern SDP and the anode electrode 134 can be joined by applying heat and pressure during the transfer process of the light-emitting element ED. Through the eutectic bonding, the light-emitting element ED can be bonded to the solder pattern SDP and the first electrode CE1 without a separate adhesive material. For example, the solder pattern SDP can be made of indium (In), tin (Sn) or alloys thereof. However, example embodiments of the present disclosure are not limited thereto. For example, the solder pattern SDP can be a bonding pad or a joining pad. However, the example embodiments of the present disclosure are not limited thereto.

According to the present disclosure, a passivation layer 116 can be disposed on the plurality of signal lines TL, the plurality of first electrodes CE1, the plurality of contact electrodes CCE, and the third insulating layer 115c. For example, the passivation layer 116 can be disposed in the display area AA, the first non-display area NA1, and the second non-display area NA2. A portion of the passivation layer 116 disposed in the bending area BA can be removed. A portion of the passivation layer 116 covering the plurality of pad electrodes PE in the second non-display area NA2 can be removed. Since the passivation layer 116 is disposed to cover the remaining area except the bending area BA, the plurality of pad electrodes PE, and the area where the solder pattern SDP is disposed, the penetration of moisture or impurities into the light-emitting element ED can be reduced. For example, the passivation layer 116 can be configured in a single-layer or multi-layer structure of silicon oxide (SiOx) or silicon nitride (SiNx). For example, the passivation layer 116 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si). However, the example embodiments of the present disclosure are not limited thereto. For example, the passivation layer 116 can be a planarization layer or an insulating layer. However, the example embodiments of the present disclosure are not limited thereto. For example, the passivation layer 116 can include a hole through which the solder pattern SDP is exposed.

In each of the plurality of sub-pixels, the light-emitting element ED can be disposed on the solder pattern SDP. In the first sub-pixel SP1 the first light-emitting element 130 can be disposed. In the second sub-pixel SP2 the second light-emitting element 140 can be disposed. In the third sub-pixel SP3 the third light-emitting element 150 can be disposed.

The light-emitting element ED can be formed on a silicon wafer by a method such as Metal Organic Chemical Vapor Deposition (MOCVD), Chemical Vapor Deposition (CVD), Plasma-Enhanced Chemical Vapor Deposition (PECVD), Molecular Beam Epitaxy (MBE), Hydride Vapor Phase Epitaxy (HVPE), sputtering, or the like. However, the example embodiments of the present disclosure are not limited thereto.

Referring to FIG. 9, the first light-emitting element 130 can include the anode electrode 134, a first semiconductor layer 131, an active layer 132, a second semiconductor layer 133, a cathode electrode 135, and a encapsulation film 136. However, the example embodiments of the present disclosure are not limited thereto. For example, the first light-emitting element 130 may not include the encapsulation film 136.

The first semiconductor layer 131 can be disposed on a solder pattern SDP. The second semiconductor layer 133 can be disposed on the first semiconductor layer 131.

For example, one of the first semiconductor layer 131 and the second semiconductor layer 133 can be made of a compound semiconductor of group III-V, group II-VI, or the like, and can be doped with an impurity or dopant. For example, one of the first semiconductor layer 131 and the second semiconductor layer 133 can be a semiconductor layer doped with an n-type impurity, and the other thereof can be a semiconductor layer doped with a p-type impurity. However, the example embodiments of the present disclosure are not limited thereto. For example, one of the first semiconductor layer 131 and the second semiconductor layer 133 can be a layer where an n-type or p-type impurity is doped in a material such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the example embodiments of the present disclosure are not limited thereto. For example, the n-type impurity can be silicon (Si), germanium (Ge), selenium (Se), carbon (C), tellurium (Te), tin (Sn), or the like. However, the example embodiments of the present disclosure are not limited thereto. For example, the p-type impurity can be magnesium (Mg), zinc (Zn), calcium (Ca), strontium (Sr), barium (Ba), beryllium (Be), or the like. However, the example embodiments of the present disclosure are not limited thereto.

For example, the first semiconductor layer 131 and the second semiconductor layer 133 can be a nitride semiconductor containing an n-type impurity and a nitride semiconductor containing a p-type impurity, respectively. However, the example embodiments of the present disclosure are not limited thereto. For example, the first semiconductor layer 131 can be a nitride semiconductor containing a p-type impurity, and the second semiconductor layer 133 can be a nitride semiconductor containing an n-type impurity. However, the example embodiments of the present disclosure are not limited thereto.

The active layer 132 can be disposed between the first semiconductor layer 131 and the second semiconductor layer 133. The active layer 132 can receive holes and electrons from the first semiconductor layer 131 and the second semiconductor layer 133 to emit light. For example, the active layer 132 can be composed of one of a single well structure, a multi-well structure, a single quantum well structure, a multi-quantum well (MQW) structure, a quantum dot structure, and a quantum wiring structure. However, the example embodiments of the present disclosure are not limited thereto. For example, the active layer 132 can be made of indium gallium nitride (InGaN) or gallium nitride (GaN). However, the example embodiments of the present disclosure are not limited thereto.

In another example, the active layer 132 can include a multi-quantum well (MQW) structure having a well layer and a barrier layer having a higher band gap than the well layer. For example, the active layer 132 can include a InGaN layer as a well layer and an AlGaN layer as a barrier layer. However, the example embodiments of the present disclosure are not limited thereto.

The anode electrode 134 can be disposed between the first semiconductor layer 131 and the solder pattern SDP. For example, the anode electrode 134 can electrically connect the first semiconductor layer 131 with the first electrode CE1. The anode voltage output from the pixel driving circuit PD can be applied to the first semiconductor layer 131 through the signal line TL, the first electrode CE1, and the anode electrode 134. For example, the anode electrode 134 can be made of a conductive material capable of eutectic bonding with the solder pattern SDP. However, the example embodiments of the present disclosure are not limited thereto. For example, the anode electrode 134 can be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or any alloy thereof. However, the example embodiments of the present disclosure are not limited thereto.

The cathode electrode 135 can be disposed on the second semiconductor layer 133. For example, the cathode electrode 135 can electrically connect the second semiconductor layer 133 with the second electrode CE2. The cathode voltage output from the pixel driving circuit PD can be applied to the second semiconductor layer 133 through the contact electrode CCE, the second electrode CE2, and the cathode electrode 135. The cathode electrode 135 can be made of a transparent conductive material so that light emitted from the light-emitting element ED can be directed upwards from the light-emitting element ED. However, the example embodiments of the present disclosure are not limited thereto. For example, the cathode electrode 135 can be made of a material such as indium tin oxide (ITO), indium zinc oxide (IZO), indium gallium zinc oxide (IGZO), or the like. However, the example embodiments of the present disclosure are not limited thereto.

The encapsulation film 136 can be disposed on at least a portion of the first semiconductor layer 131, the active layer 132, the second semiconductor layer 133, the anode electrode 134, and the cathode electrode 135. For example, the encapsulation film 136 can surround at least a portion of the first semiconductor layer 131, the active layer 132, the second semiconductor layer 133, the anode electrode 134, and the cathode electrode 135.

For example, the encapsulation film 136 can protect the first semiconductor layer 131, the active layer 132, and the second semiconductor layer 133. For example, the encapsulation film 136 can be disposed on the side surface of the first semiconductor layer 131, the side surface of the active layer 132, and the side surface of the second semiconductor layer 133.

For example, the encapsulation film 136 can be disposed on at least a portion of the anode electrode 134 and the cathode electrode 135, for example, an edge portion or a border portion or one side of the anode electrode 134 and an edge portion or a border portion or one side of the cathode electrode 135. At least a portion of the anode electrode 134 can be exposed from the encapsulation film 136 so that the anode electrode 134 and the solder pattern SDP can be connected to each other. For example, at least a portion of the cathode electrode 135 can be exposed from the encapsulation film 136 so that the cathode electrode 135 and the second electrode CE2 can be connected to each other. For example, the encapsulation film 136 can be made of an insulating material such as silicon nitride (SiNx) or silicon oxide (SiOx). For example, the encapsulation film 136 can be formed by inorganic film in a single layer or in multiple layers, for example, the inorganic film in a single layer can be a silicon oxide (SiOx) film or a silicon nitride (SiNx) film, and inorganic films in multiple layers can formed by alternately stacking one or more silicon oxide (SiOx) films, one or more silicon nitride (SiNx) films, and one or more amorphous silicon (a-Si). However, the example embodiments of the present disclosure are not limited thereto.

In another example, the encapsulation film 136 can be made of a resin layer in which a reflective material is dispersed. However, the example embodiments of the present disclosure are not limited thereto. For example, the encapsulation film 136 can be manufactured as a reflector having various structures. However, the example embodiments of the present disclosure are not limited thereto. Light emitted from the active layer 132 can be reflected upward by the encapsulation film 136, so that light extraction efficiency can be improved. For example, the encapsulation film 136 can be a reflective layer. However, the example embodiments of the present disclosure are not limited thereto.

According to the present disclosure, the light-emitting element ED is described as having a vertical structure. However, the example embodiments of the present disclosure are not limited thereto. For example, the light-emitting element ED can have a lateral structure or a flip chip structure.

Although the first light-emitting element 130 has been described with reference to FIG. 9, the second light-emitting element 140 and the third light-emitting element 150 can have structures substantially identical or similar to that of the first light-emitting element 130. For example, the second light-emitting element 140 and the third light-emitting element 150 can include layers substantially identical to or similar to the first semiconductor layer 131, the active layer 132, the second semiconductor layer 133, the anode electrode 134, the cathode electrode 135, and the encapsulation film 136 of the first light-emitting element 130.

According to the present disclosure, a first optical layer 117a surrounding a plurality of light-emitting elements ED can be disposed in the display area AA. For example, the first optical layer 117a can be disposed to cover a plurality of light-emitting elements ED and banks BNK in the areas of a plurality of sub-pixels. For example, the first optical layer 117a can cover the bank BNK, a portion of the passivation layer 116, and side surfaces of a plurality of light-emitting elements ED. The first optical layer 117a can cover or be disposed in an area between a plurality of light-emitting elements ED and between a plurality of banks BNK included in one pixel PX. For example, the first optical layers 117a can extend in a first direction and be spaced apart from each other in the second direction. For example, the first optical layer 117a can be disposed between the passivation layer 116 and the second electrode CE2 to surround the side portions of the light-emitting element ED and the bank BNK. However, the example embodiments of the present disclosure are not limited thereto. For example, the first optical layer 117a can be a diffusion layer or a sidewall diffusion layer. However, the example embodiments of the present disclosure are not limited thereto.

The first optical layer 117a can include an organic insulating material having fine particles dispersed therein. However, the example embodiments of the present disclosure are not limited thereto. For example, the first optical layer 117a can be made of siloxane in which fine particles such as titanium dioxide (TiO2) particles are dispersed. However, the example embodiments of the present disclosure are not limited thereto. Light from the plurality of light-emitting elements ED can be scattered by fine particles dispersed in the first optical layer 117a and emitted to the outside of the display device 1000. Accordingly, the first optical layer 117a can improve the extraction efficiency of light emitted from the plurality of light-emitting elements ED.

For example, the first optical layer 117a can be disposed in each of the plurality of pixels PX, or can be disposed commonly in some of the pixels PX disposed in the same row. However, the example embodiments of the present disclosure are not limited thereto. For example, the first optical layer 117a can be disposed in each of a plurality of pixels PX, or a plurality of pixels PX can share one first optical layer 117a. In another example, each of the plurality of sub-pixels can separately include a first optical layer 117a. However, the example embodiments of the present disclosure are not limited thereto.

According to the present disclosure, a second optical layer 117b can be disposed on the passivation layer 116 in the display area AA. For example, the second optical layer 117b can be disposed to surround the first optical layer 117a. For example, the second optical layer 117b can be in contact with a side surface of the first optical layer 117a. For example, the second optical layer 117b can be disposed in an area between adjacent ones of a plurality of pixels PX. However, the example embodiments of the present disclosure are not limited thereto. For example, the second optical layer 117b can be a diffusion layer, a diffusion layer window, a window diffusion layer, or the like. However, the example embodiments of the present disclosure are not limited thereto.

The second optical layer 117b can be made of an organic insulating material. However, the example embodiments of the present disclosure are not limited thereto. The second optical layer 117b can be made of the same material as the first optical layer 117a. For example, the second optical layer 117b can be made of siloxane in which fine metal particles such as titanium dioxide (TiO2) particles are dispersed. However, the example embodiments of the present disclosure are not limited thereto. For example, the first optical layer 117a can include fine particles, and the second optical layer 117b may not include fine particles. For example, the second optical layer 117b can be made of siloxane. However, the example embodiments of the present disclosure are not limited thereto.

For example, the thickness of the first optical layer 117a can be smaller than the thickness of the second optical layer 117b. However, the example embodiments of the present disclosure are not limited thereto. Accordingly, when viewed in a cross-sectional view of the display device 1000, the first optical layer 117a can include a concave portion that is recessed inward more than the upper surface of the second optical layer 117b.

According to the present disclosure, the second electrode CE2 can be disposed on the first optical layer 117a and the second optical layer 117b. For example, the second electrode CE2 can be electrically connected to the plurality of contact electrodes CCE through contact holes in the second optical layer 117b. For example, the second electrode CE2 can be disposed on a plurality of light-emitting elements ED. For example, the second electrode CE2 can include a transparent conductive oxide such as indium tin oxide (ITO) or indium zinc oxide (IZO). However, the example embodiments of the present disclosure are not limited thereto. For example, the second electrode CE2 can be disposed in contact with the cathode electrode 135. For example, the second electrode CE2 can overlap with the first optical layer 117a. For example, the second electrode CE2 can cover the upper surface of the first optical layer 117a.

The second electrode CE2 can extend continuously in the first direction of the substrate 110. Accordingly, it can be commonly connected to a plurality of pixels PX arranged in the first direction of the substrate 110. For example, the second electrode CE2 can be commonly connected to a plurality of pixels PX.

According to the present disclosure, the second electrode CE2 can extend continuously over the first optical layer 117a, the second optical layer 117b, and the light-emitting element ED. The first optical layer 117a can include a concave portion that is recessed inward more than the upper surface of the second optical layer 117b. Accordingly, a first portion of the second electrode CE2 disposed on the first optical layer 117a is disposed along the concave portion, and thus can be disposed at a lower position than a second portion of the second electrode CE2 disposed on the second optical layer 117b.

A third optical layer 117c can be disposed on the second electrode CE2. The third optical layer 117c can be disposed to overlap with the plurality of light-emitting elements ED and the first optical layer 117a. Since the third optical layer 117c is disposed on the second electrode CE2 and the plurality of light-emitting elements ED, a mura that can occur on some of the plurality of light-emitting elements ED can be alleviated. For example, when transferring the plurality of light-emitting elements ED onto the substrate 110 of the display device 1000, its process deviation or the like can cause the occurrence of an area where the spacings between the plurality of light-emitting elements ED are not uniform. If the spacings between the plurality of light-emitting elements ED are not uniform, the light emission areas of the plurality of respective light-emitting elements ED can be disposed unevenly, which can cause the mura to be visible to the user. Accordingly, since the third optical layer 117c configured to uniformly diffuse light is disposed on top of the plurality of light-emitting elements ED, it is possible to alleviate the phenomenon in which light emitted from some light-emitting elements ED looks like mura. Accordingly, since the light emitted from the plurality of light-emitting elements ED is evenly diffused by the third optical layer 117c and extracted to the outside of the display device 1000, the luminance uniformity of the display device 1000 can be improved.

The third optical layer 117c can be made of an organic insulating material having fine particles dispersed therein. However, the example embodiments of the present disclosure are not limited thereto. For example, the third optical layer 117c can be made of siloxane in which fine particles such as titanium dioxide (TiO2) particles dispersed. However, the example embodiments of the present disclosure are not limited thereto. For example, the third optical layer 117c can be made of the same material as the first optical layer 117a. However, the example embodiments of the present disclosure are not limited thereto. For example, the third optical layer 117c can be a diffusion layer or an upper surface diffusion layer. However, the example embodiments of the present disclosure are not limited thereto.

According to the present disclosure, light from a plurality of light-emitting elements ED can be scattered by fine particles dispersed in the third optical layer 117c and be emitted to the outside of the display device 1000. The third optical layer 117c can evenly mix the lights emitted from the plurality of light-emitting elements ED to further improve the luminance uniformity of the display device 1000. Furthermore, the light extraction efficiency of the display device 1000 can be improved by the light being scattered by the plurality of fine particles, thereby enabling the display device 1000 to be driven at low power.

A black matrix BM can be disposed on the second electrode CE2, the first optical layer 117a, the second optical layer 117b, and the third optical layer 117c in the display area AA. For example, the black matrix BM can fill the contact hole in the second optical layer 117b. The black matrix BM can be disposed to cover the display area AA, so that color mixing of light from a plurality of sub-pixels and external light reflection can be reduced. For example, since the black matrix BM can be disposed within the contact hole where the second electrode CE2 and the contact electrode CCE are connected to each other, light leakage between neighboring sub-pixels can be prevented.

For example, the black matrix BM can be made of an opaque material. However, the example embodiments of the present disclosure are not limited thereto. For example, the black matrix BM can be made of an organic insulating material having black pigment or black dye added thereto. For example, the black matrix BM can be formed of an organic layer such as an acryl-based material, an epoxy-based material, a phenolic-based material, a polyamide-based material, or a polyimide-based material, to which a black pigment or a black dye is added. However, the example embodiments of the present disclosure are not limited thereto.

A cover layer 118 can be disposed on the black matrix BM in the display area AA. The cover layer 118 can protect the components under the cover layer 118. For example, the cover layer 118 can be made of an organic insulating material. However, the example embodiments of the present disclosure are not limited thereto. For example, the cover layer 118 can be made of a photoresist, polyimide (PI), or photo acryl-based material, or the like. However, the example embodiments of the present disclosure are not limited thereto. For example, the cover layer 118 can be an overcoat layer or an insulating layer. However, the example embodiments of the present disclosure are not limited thereto.

The polarizing layer 293 can be disposed on the cover layer 118 via a first adhesive layer 291. The cover member 155 can be disposed on the polarizing layer 293 via the adhesive layer 295 (hereinafter, it can also be referred to as a second adhesive layer 295). For example, the first adhesive layer 291 and the second adhesive layer 295 can include an optically clear adhesive (OCA), an optically clear resin (OCR), or a pressure sensitive adhesive (PSA). However, the example embodiments of the present disclosure are not limited thereto.

According to the present disclosure, the plurality of pad electrodes PE can be disposed on the third insulating layer 115c in the second non-display area NA2. For example, at least a portion of the plurality of pad electrodes PE can be exposed from the passivation layer 116. For example, a plurality of pad electrodes PE can be electrically connected to the (2-4)-th connection line 122d through the contact hole in the third insulating layer 115c.

An adhesive layer ACF can be disposed on the plurality of pad electrodes PE. The adhesive layer ACF can be an adhesive layer in which conductive balls are dispersed in an insulating material. However, the example embodiments of the present disclosure are not limited thereto. In a case where heat or pressure is applied to the adhesive layer ACF, the conductive balls can be electrically connected in the part where the heat or pressure is applied, thereby providing conductive property. By placing the adhesive layer ACF between a plurality of pad electrodes PE and the flexible circuit board (or flexible film) 157, the flexible circuit board (or flexible film) 157 can be attached or bonded to a plurality of pad electrodes PE. For example, the adhesive layer ACF can be an anisotropic conductive film. However, the example embodiments of the present disclosure are not limited thereto.

The flexible circuit board (or flexible film) 157 can be disposed on the adhesive layer ACF. The flexible circuit board (or flexible film) 157 can be electrically connected to the plurality of pad electrodes PE through the adhesive layer ACF. Accordingly, signals output from the flexible circuit board (or flexible film) 157 and the printed circuit board can be transmitted to the pixel driving circuit PD in the display area AA through the plurality of pad electrodes PE, the (2-4)-th connection line 122d, the (2-3)-th connection line 122c, the (2-2)-th connection line 122b, and the (2-1)-th connection line 122a.

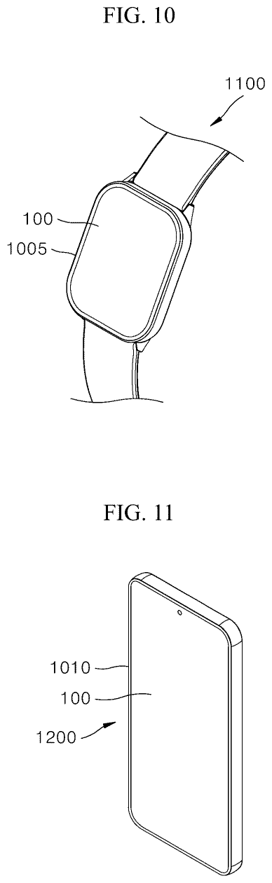

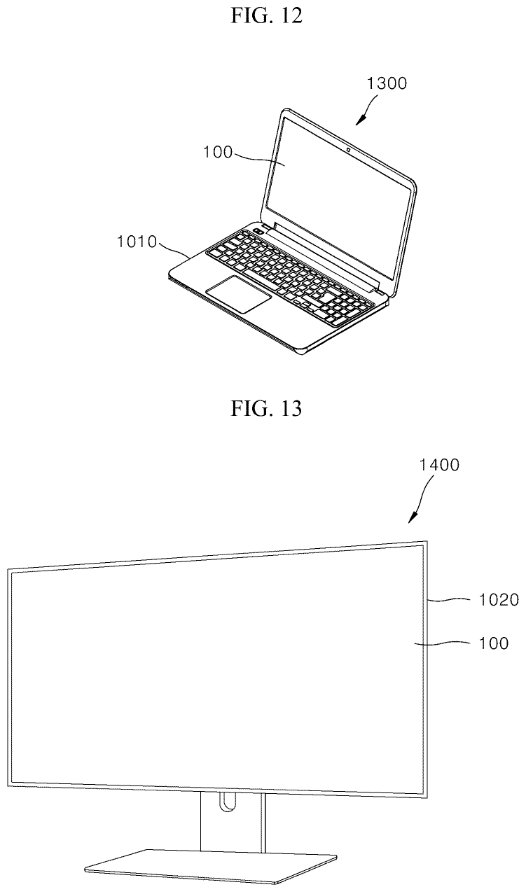

FIG. 10, FIG. 11, FIG. 12 and FIG. 13 are views illustrating devices to which display devices according to example embodiments of the present disclosure are applied.

Referring to FIGS. 10 to 13, the display device 1000 according to the example embodiments of the present disclosure can be included in various devices or electronic devices. For example, referring to FIGS. 10 to 13, various electronic devices can include a wearable device 1100, a mobile device 1200, a notebook 1300, and a monitor or TV 1400. However, the example embodiments of the present disclosure are not limited thereto.

Each of the wearable device 1100, the mobile device 1200, the notebook 1300, and the monitor or TV 1400 can include a case 1005, 1010, 1015, 1020, and the display panel 100 (or the display device 1000) according to the example embodiment of the present disclosure described with reference to FIGS. 1 to 9.

For example, the display device according to the example embodiment of the present disclosure can be applied to a mobile device, a video phone, a smart watch, a watch phone, a wearable device, a foldable device, a rollable device, a bendable device, a flexible device, a curved device, a sliding device, a variable device, an electronic notebook, an electronic book, a portable multimedia player (PMP), a personal digital assistant (PDA), an MP3 player, a mobile medical device, a desktop PC, a laptop PC, a netbook computer, a workstation, a navigation system, a vehicle display device, a theater display device, a television, a wallpaper device, a signage device, a game device, a notebook, a monitor, a camera, a camcorder, home appliances, or the like.

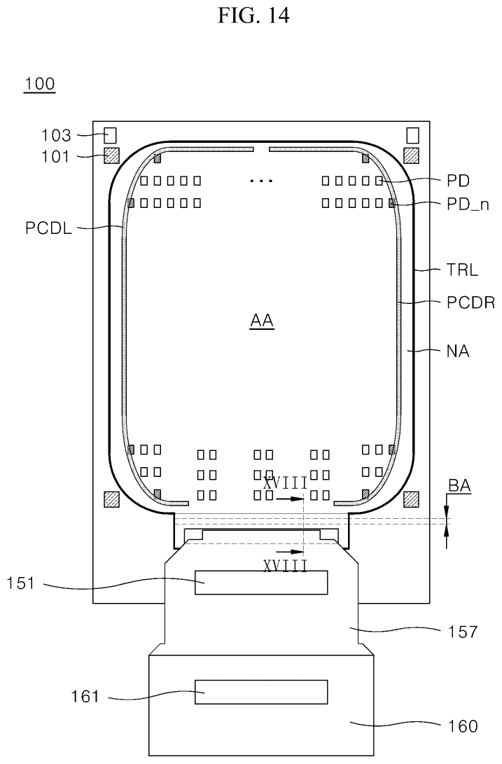

FIG. 14 is a plan view of a display panel according to an example embodiment of the present disclosure.

Referring to FIG. 14, the flexible circuit board 157 and the printed circuit board 160 can be connected to one side of the display panel 100. The flexible circuit board 157 and the printed circuit board 160 can be disposed at least on one side edge of the display panel 100. One side of the flexible circuit board 157 can be attached to the display panel 100, and the other side thereof can be attached to the printed circuit board 160.

The flexible circuit board 157 can provide power or signals supplied from the printed circuit board 160 to a plurality of pixel driving circuits of the display panel 100.

The flexible circuit board 157 can include a control circuit, which is a timing controller 151. The printed circuit board 160 can include a power management integrated circuit 161.

The display panel 100 can include a display area AA where an image is displayed and a non-display area NA where an image is not displayed. The display panel 100 can include a trimming line TRL along an outer edge of the non-display area NA. The trimming line TRL can refer to an area cut by a laser during a scribing process to separate a plurality of individual unit display panels 100 from a mother substrate. An area located outside the trimming line TRL can be removed through the scribing process.

In the display area AA a plurality of driving chips PD and a plurality of pixels including a plurality of light-emitting elements electrically connected to the plurality of driving chips PD can be arranged. Each driving chip PD can control the light-emitting operation of the plurality of light-emitting elements by supplying control signals and power to the plurality of light-emitting elements. Each driving chip PD can be a micro driver.

The display panel 100 can have a shape whose one side is longer than another side thereof. For example, the display panel 100 can include a long side and a short side that is shorter than the long side.

The display panel 100 can include one or more crack detection lines PCDL, PCDR disposed in a portion of the non-display area NA. Each of one or more crack detection lines PCDL, PCDR can be disposed along the outer part of the display area AA to detect defects such as cracks that can occur in the outer part of the display area AA. One or more crack detection lines PCDL, PCDR can be disposed to surround at least a portion of both side areas, upper and lower areas of the display area AA. For example, the one or more crack detection lines PCDL, PCDR can include a first crack detection line PCDL and a second crack detection line PCDR.

The first crack detection line PCDL can extend along a left long side of the display panel 100 and can extend to each of upper and lower left corners of the display panel 100 and then can extend along a left portion of each of upper and lower short sides of the display panel 100. The second crack detection line PCDR can extend along a right long side of display panel 100 and can extend to each of upper and lower right corners of the display panel 100 and then can extend along a right portion of each of the upper and lower short sides of the display panel 100. The first crack detection line PCDL and the second crack detection line PCDR can be disposed spaced apart from each other.

The first crack detection line PCDL and the second crack detection line PCDR can be disposed to overlap with some driving chips of the plurality of driving chips PD at the corner area of the display panel 100. The driving chip disposed to overlap with the first and second crack detection lines PCDL, PCDR at the corner area can be an inactive driving chip PD_n.

Each of the driving chips PD arranged in the display area AA can be an active driving chip capable of supplying control signals and power to a plurality of light-emitting elements to control light-emitting operations of the plurality of light-emitting elements. In order for each driving chip PD to control the plurality of light-emitting elements, not only power line but also signal line for controlling the on/off or light-emitting time of the light-emitting elements are required.

The inactive driving chip PD_n may not be electrically connected to at least some of the power lines or the signal lines as it is disposed to overlap with the first crack detection line PCDL or the second crack detection line PCDR at the corner area of the display panel 100. Accordingly, the inactive driving chip PD_n can be an unused driving chip that cannot control the plurality of light-emitting elements. Eight inactive driving chips PD_n can be positioned along the corner areas of the display panel 100.

In the outer side of the trimming line TRL a plurality of alignment key patterns 101, 103 can be disposed. The plurality of alignment key patterns 101, 103 can include a first alignment key pattern 101 and a second alignment key pattern 103. However, the example embodiments of the present disclosure are not limited thereto.

The first alignment key pattern 101 can be a pattern for alignment between the display panel 100 and the cover member 155 of FIG. 1. A plurality of first alignment key patterns 101 can be positioned in at least one of each outer side area of the trimming line TRL facing each corner area of the display panel 100. For example, the plurality of first alignment key patterns 101 can be comprised of four alignment key patterns, each being disposed at a respective one of four corner areas of the display panel 100.

The second alignment key pattern 103 can include various alignment key patterns for aligning components disposed in different layers, such as a plurality of signal lines, a plurality of contact holes, and a plurality of driving chips disposed on the display panel 100, to the correct positions. The second alignment key pattern 103 can include a metal material. Accordingly, the second alignment key pattern 103 can be disposed in the display area AA or the non-display area NAA, and be formed together with a plurality of signal lines including a metal material. However, example embodiments of the present disclosure are not limited thereto.

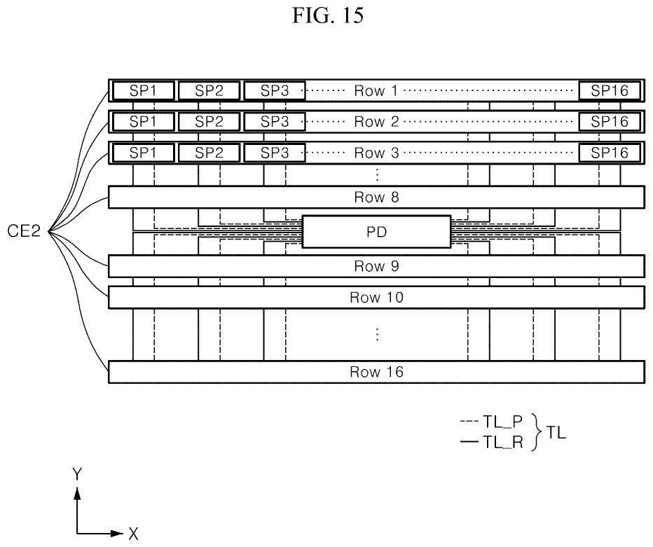

FIG. 15 is a plan view showing an area where one of the plurality of driving chips of FIG. 14 is disposed.

Referring to FIG. 15, the plurality of driving chips PD can be arranged in a matrix shape in the display area AA. Referring to FIG. 15, with respect to one driving chip PD, a plurality of pixels PX1 to PX16 including a plurality of light-emitting elements can be arranged in a matrix shape. A plurality of pixels can be arranged to be spaced apart from each other in a first direction and a second direction intersecting the first direction. The first direction can be the X-axis direction of the display panel 100, and the second direction can be the Y-axis direction of the display panel 100. However, example embodiments of the present disclosure are not limited thereto. For example, the first direction can be the horizontal direction or row direction of the display panel 100, and the second direction can be the vertical direction or column direction of the display panel 100.

In the first direction of the display panel 100, sub-pixels emitting light of different colors can be disposed alternately. Additionally, sub-pixels emitting light of the same color can be disposed in the second direction of the display panel 100. For example, the first pixel PX1 to the sixteenth pixel PX16 can be arranged in the row direction, which is the first direction. A single pixel PX can include sub-pixels of red R, green G, and blue B. Accordingly, in the first direction, which is the row direction, for example, the sub-pixels of red R, green G, and blue B can be disposed in a repeating order.

A plurality of light-emitting elements can be disposed corresponding to each sub-pixel. At least one light-emitting element can be disposed in one sub-pixel. For example, two light-emitting elements can be disposed in one sub-pixel. One of the two light-emitting elements can be a main light-emitting element and the other thereof can be a redundant light-emitting element. The light-emitting element can be a micro LED.

Additionally, sub-pixels emitting light of the same color can be disposed in the second direction, for example, the column direction. For example, sub-pixels of one color among red R, green G, or blue B can be disposed in the second direction, for example, the column direction. Sub-pixels emitting light of the same color can be electrically connected to each other via one signal line TL_P or TL_R.

The signal line TL can include a main line TL_P and a redundancy line TL_R. The main line TL_P and the redundancy line TL_R can be disposed spaced apart from each other in the first direction of the display panel 100. The main line TL_P can be connected to the main light-emitting element through the first electrode CE1, and the redundancy line TL_R can be connected to the redundant light-emitting element through the first electrode CE1.

Each of the plurality of second electrodes CE2 can extend in the first direction. Additionally, each of the plurality of second electrodes CE2 can be arranged to be spaced apart from each other in the second direction. Accordingly, each second electrode CE2 can extend in the first direction to be connected to each of the first to sixteenth pixels PX1 to PX16 disposed in each of a plurality of rows Row 1, Row 2, Row 3, . . . , Row 16.

One driving chip PD can include a plurality of driving circuits to drive a plurality of light-emitting elements. One driving chip PD can be connected to a plurality of second electrodes CE2 and a plurality of signal lines TL connected to a plurality of pixels PX1, PX2, . . . , PX16. For example, one driving chip PD can drive a plurality of light-emitting elements arranged on the first to sixteenth rows Row 1 to Row 16. In other words, one driving chip PD can be electrically connected to a plurality of light-emitting elements arranged on the first to sixteenth rows Row 1 to Row 16 through a plurality of signal lines TL and a plurality of second electrodes CE2, and can control the light-emitting operations of the plurality of light-emitting elements by supplying control signals and power to the plurality of light-emitting elements through the plurality of signal lines TL and the plurality of second electrodes CE2.

The plurality of signal lines TL can be radially connected to the driving chip PD to connect a plurality of pixels PX1, PX2, . . . , PX16 arranged in each of the plurality of rows Row 1, Row 2, Row 3, . . . , Row 16 to the driving chip PD. For example, when viewed from above the display panel 100, a shape in which the plurality of signal lines TL are connected to the driving chip PD can look like a rhombus shape in the area around the driving chip PD. For example, when viewed from above the display panel 100, the arrangement shape of the plurality of connection lines connecting the plurality of signal lines TL and the driving chip PD can look like a rhombus shape in the area around the pixel driving circuit PD.

The display device according to an example embodiment of the present disclosure can have an in-cell touch structure that uses each of a plurality of second electrodes CE2 as a touch electrode instead of forming separate touch panel. Accordingly, the thickness of the display panel can be reduced since separate touch panel is not formed.

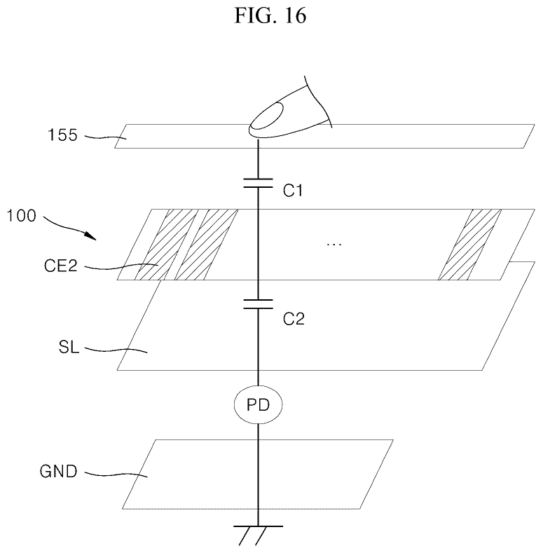

FIG. 16 is a diagram illustrating touch operation of a display device according to an example embodiment of the present disclosure.

Referring to FIG. 16, when a user's touch operation is performed on the cover member 155, a change in a first capacitance C1 between the plurality of second electrodes CE2 disposed on the display panel 100 and the cover member 155, and a change in a second capacitance C2 between the plurality of second electrodes CE2 and the plurality of signal lines SL can be detected and provided to the driving chip PD. And the driving chip PD can perform a role of a touch controller to provide a control signal for operation according to the touch input to a plurality of light-emitting elements. On one side facing opposite to the cover member 155 a grounding part GND can be disposed.

The display device 1000 according to an example embodiment of the present disclosure can perform touch driving and touch sensing in a self-capacitance-based touch sensing manner, or can perform touch driving and touch sensing in a mutual-capacitance-based touch sensing manner.

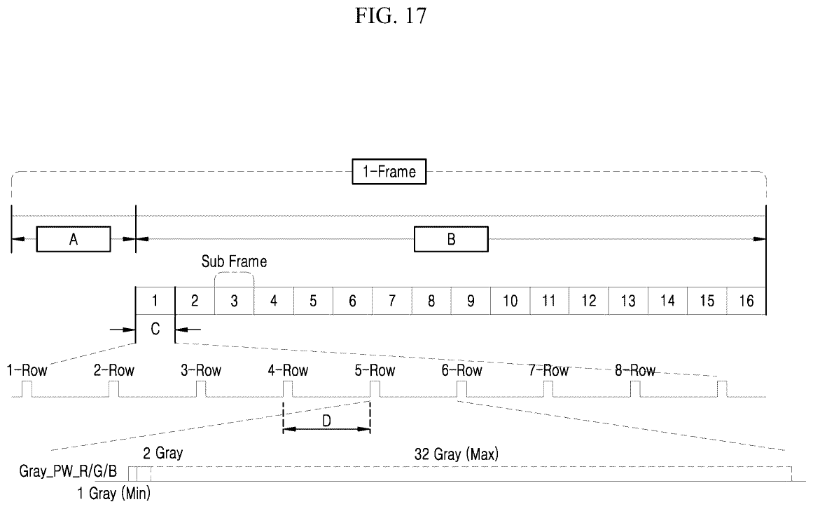

FIG. 17 is a diagram illustrating an example of a signal waveform diagram when driving a display device according to an example embodiment of the present disclosure.

Referring to FIG. 17, the display device according to an example embodiment of the present disclosure can perform an emission operation in units of one frame.

One frame can include a touch period A and a display period B.

One frame can operate at a frequency of, for example, 60 Hz. In this case, the touch period A can operate for a first time period at a frequency of, for example, 60 Hz, and the display period B can operate for a second time period longer than the first time period at a frequency of, for example, 60 Hz. Therefore, the operation time of the touch period A and the operation time of the display period B within one frame can be different from each other. For example, the operation time of the touch period A can be shorter than the operation time of the display period B.

The display period B can include sixteen sub-frames.

For example, in a case where eight micro LEDs are connected to each signal line connected to a driving chip in a display panel, one sub-frame period C can include eight pulse signals 1-Row, 2-Row, 3-Row, 4-Row, 5-Row, 6-Row, 7-Row, 8-Row. For example, in the example embodiment of the present disclosure eight micro LEDs can operate during one sub-frame.

Therefore, in the example embodiment of the present disclosure, since one frame includes sixteen sub-frames and one sub-frame includes eight pulse signals, 128 micro LEDs can operate during one frame.

The example embodiment of the present disclosure is not limited thereto. For example, in a case where sixteen micro LEDs are connected to each signal line connected to the driving chip, one sub-frame period C can include sixteen pulse signals. In this case, 256 micro LEDs can operate during one frame.

One pulse signal (e.g., 5-Row) drives one micro LED. One pulse signal period D can include a high signal period and a low signal period. In this regard, the length of time of the low signal period can be greater than that of the high signal period.

In an example embodiment of the present disclosure, the driving time of a micro LED can be controlled based on an light-emitting signal EM applied to a gate electrode of a light-emitting transistor T_{EM}.

The micro driver can control the application time of the light-emitting signal EM with the pulse width PW. For example, in a case where one pulse signal (e.g., 5-Row) with one pulse width PW is applied to the gate electrode of a light-emitting transistor T_{EM}, it can be called 1 Gray.

The micro driver can control the application time of the light-emitting signal EM by adjusting the pulse width PW from minimum 1 Gray to maximum 32 Gray for one pulse signal (e.g., 5-Row).

A single pixel PX can include sub-pixels of red R, green G, and blue B. Each of the plurality of micro LEDs can be disposed in each sub-pixel.

Therefore, the micro driver can control the light-emitting time of the micro LED corresponding to each sub-pixel of red R, green G, or blue B by applying a pulse signal with a pulse width PW adjusted from at least 1 Gray (Min) to at most 32 Gray (Max) to the gate electrode of the light-emitting transistor T_{EM}.

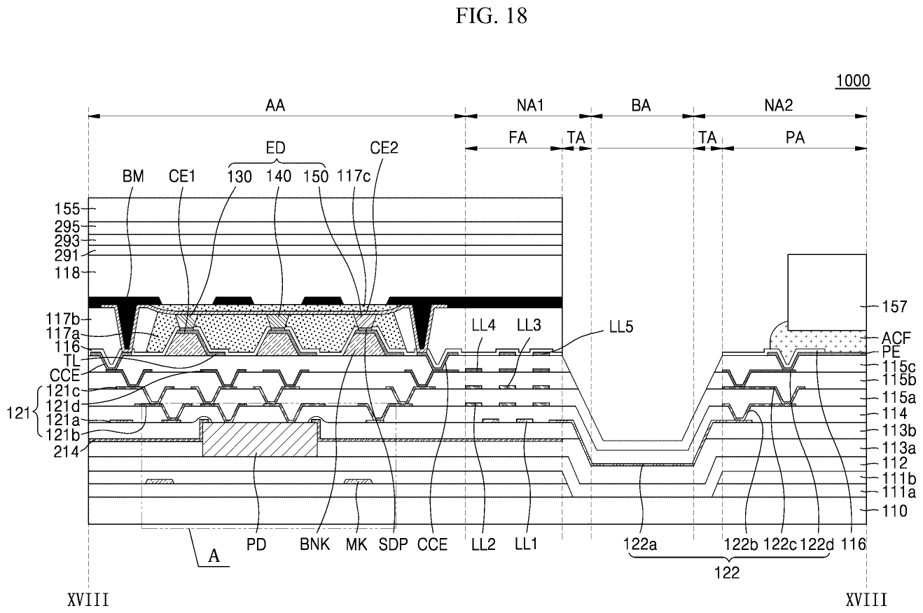

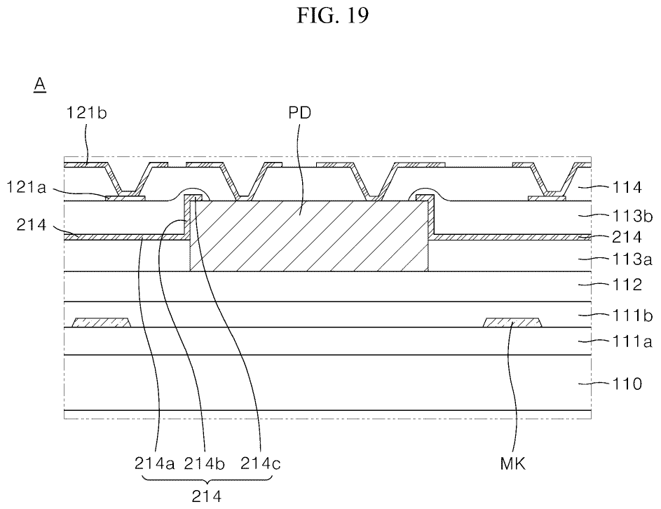

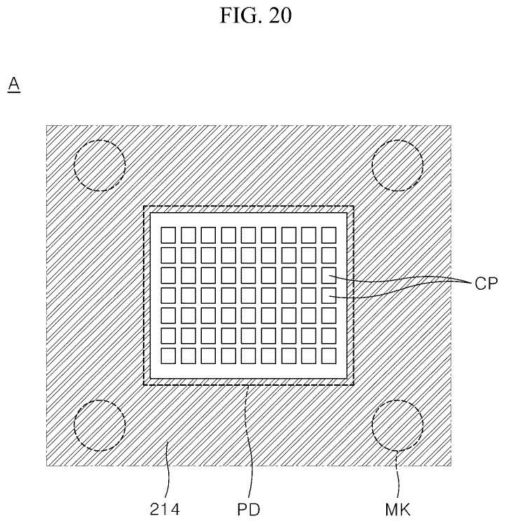

FIG. 18 is a cross-sectional view taken along a cutting line XVIII-XVIII of FIG. 14. FIG. 19 is an enlarged view of an area ‘A’ of FIG. 18. FIG. 20 is a plan view illustrating the area ‘A’.

In FIGS. 18 to 20, the same reference numerals as those as assigned to the components as described with reference to FIGS. 1 to 9 are assigned to the same components as the components as described with reference to FIGS. 1 to 9, and a description thereof will be briefly made or omitted.

Referring to FIGS. 18 to 20, the display panel can include a display area AA and a non-display area NA, and the non-display area NA can include a fan-out area FA, a bending area BA, a tapered area TA, and a pad area PA.

In the display area AA, a plurality of light emitting elements 130, 140, and 150 and at least one driving chip PD electrically connected to the plurality of light emitting elements 130, 140, and 150 can be disposed. Each of the plurality of light-emitting elements 130, 140, and 150 can include one or more sub light-emitting element. For example, each of the plurality of light-emitting elements 130, 140, and 150 can include only one sub light-emitting element. For example, the first light-emitting element 130 can include a (1-1)-th light-emitting element 130a disposed in the (1-1)-th sub-pixel SP1a and a (1-2)-th light-emitting element 130b disposed in the (1-2)-th sub-pixel SP1b. The second light-emitting element 140 can include a (2-1)-th light-emitting element 140a disposed in the (2-1)-th sub-pixel SP2a and a (2-2)-th light-emitting element 140b disposed in the (2-2)-th sub-pixel SP2b. The third light-emitting element 150 can include a (3-1)-th light-emitting element 150a disposed in the (3-1)-th sub-pixel SP3a and a (3-2)-th light-emitting element 150b disposed in the (3-2)-th sub-pixel SP3b. However, the disclosure is not limited thereto. For example, the plurality of light-emitting elements can include a fourth light-emitting element emitting white light. The fourth light-emitting element can also include one or more sub light-emitting element.

For example, each of the plurality of light-emitting elements 130, 140, and 150 can include only one sub light-emitting element. The first light-emitting element 130, the second light-emitting element 140, and the third light-emitting element 150 can have a same size (e.g., a volume) or different sizes. For example, the first light-emitting element 130 among the first light-emitting element 130, the second light-emitting element 140, and the third light-emitting element 150 can have the largest size (e.g., a volume). The second light-emitting element 140 and the third light-emitting element 150 can have the same size. For example, the size of second light-emitting element 140 and the size of the third light-emitting element 150 are same and are smaller than that of the first light-emitting element 130, but not limited thereto.

The solder pattern SDP can have a width equal to or smaller than a width of the lower end of the first light-emitting element 130, and can have a width greater than or equal to a width of the lower end of each of the second light-emitting element 140 and the third light-emitting element 150, but not limited thereto. Alternatively, the solder pattern SDP can have a width equal to or smaller than a width of the lower end of each of the first light-emitting element 130, the second light-emitting element 140 and the third light-emitting element 150.

The solder pattern SDP can include a plurality of solder patterns SDP1, SDP2, and SDP3. The plurality of solder patterns SDP1, SDP2, and SDP3 can include a first solder pattern SDP1 corresponding to the first light-emitting element 130, a second solder pattern SDP2 corresponding to the second light-emitting element 140, and a third solder pattern SDP3 corresponding to the third light-emitting element 150.

The size of the first light-emitting element 130 can be greater than the size of each of the second light-emitting element 140 and the third light-emitting element 150. For example, when the size of the upper end of the first light-emitting element 130 can be 7 to 7.6 micrometers (μm) and the size of the lower end thereof is 4.7 to 5.3 micrometers (μm), the size of the upper end of each of the second light-emitting element 140 and the third light-emitting element 150 can be 5.7 to 6.3 micrometers (μm) and the size of the lower end thereof can be 3.7 to 4.3 micrometers (μm). For example, when the size of the upper end of the first light-emitting element 130 can be 7.3 micrometers (μm) and the size of the lower end thereof is 5 micrometers (μm), the size of the upper end of each of the second light-emitting element 140 and the third light-emitting element 150 can be 6 micrometers (μm) and the size of the lower end thereof can be 4 micrometers (μm), but not limited thereto.

Since the size of the first light-emitting element 130 is larger than the size of each of the second light-emitting element 140 and the third light-emitting element 150, the first solder pattern SDP1 can have a width greater than the width of each of the second solder pattern SDP2 and the third solder pattern SDP3.

The first solder pattern SDP1 can have a width smaller than an upper end width of the first light-emitting element 130 and larger than a lower end width of the first light-emitting element 130. The second solder pattern SDP 2 can have a width smaller than an upper end width of the second light-emitting element 140 and larger than a lower end width of the second light-emitting element 140. The third solder pattern SDP3 can have a width smaller than the upper end width of the third light-emitting element 150 and larger than the lower end width of the third light-emitting element 150, but not limited thereto.

The first planarization layer 113a and the second planarization layer 113b disposed on the adhesive layer 112 can be disposed to surround a side surface of at least one driving chip PD. However, example embodiments of the present disclosure are not limited thereto. For example, the second planarization layer 113b can be disposed to cover at least a portion of an upper surface of the driving chip PD.

The first planarization layer 113a can be disposed to surround a lower portion of a side surface of the driving chip PD. The second planarization layer 113b can be disposed on the first planarization layer 113a and can be disposed to surround an upper portion of a side surface of the driving chip PD.

A protective film 214 can be disposed between the driving chip PD and the second planarization layer 113b and between the first planarization layer 113a and the second planarization layer 113b. The protective film 214 can cover an upper portion of a side surface of the driving chip PD and be disposed between the first planarization layer 113a and the second planarization layer 113b. The protective film 214 can be disposed over an entirety of the display area AA. The protective film 214 can be disposed not only in the display area AA but also in the first non-display area NA1 including the fan-out area FA. In an example embodiment, the protective film 214 can be additionally disposed in the pad area PA. The protective film 214 can be disposed between the first planarization layer 113a and the second planarization layer 113b in the pad area PA. The protective film 214 can be removed from the bending area BA. The protective film 214 may not be disposed in the bending area BA.

The protective film 214 can include a first portion 214a disposed on the upper surface of the first planarization layer 113a, a second portion 214b disposed on the upper portion of the side surface of the driving chip PD, and a third portion 214c disposed on an edge portion of the upper surface of the driving chip PD. Referring to FIG. 20, when the driving chip PD has a quadrangular upper surface, the protective film 214 can be disposed to cover four edge portions of the upper surface of the driving chip PD. The protective film 214 may not cover chip pads CP disposed on the upper surface of the driving chip PD. The protective film 214 may not cover the chip pads CP on the upper surface of the driving chip PD so as to be exposed.

The second planarization layer 113b can be disposed on the protective film 214. The second planarization layer 113b can cover an entirety of the protective film 214. The second planarization layer 113b can cover the third portion 214c of the protective film 214 disposed on the edge portion of the upper surface of the driving chip PD. For example, the second planarization layer 113b can be removed from the bending area BA. The second planarization layer 113b may not be disposed in the bending area BA.

The (1-1)-th connection line 121b and the third planarization layer 114 can be disposed on the second planarization layer 113b. The (1-2)-th connection line 121b can be disposed on the third planarization layer 114, and can extend through the third planarization layer 114 so as to be connected to the driving chip PD and the (1-1)-th connection line 121a.

The protective film 214 can enhance an adhesive force between the driving chip PD and the second planarization layer 113b, thereby preventing a void from occurring between the driving chip PD and the second planarization layer 113b due to a difference between thermal expansion coefficients of the driving chip PD and the second planarization layer 113b during a subsequent process including a heat treatment process. Since the formation of the void between the driving chip PD and the second planarization layer 113b is prevented due to the protective film 214, a structural defect in which a chemical solution used in a manufacturing process or moisture can be permeated through the void to damage the driving chip PD or the third planarization layer 114 disposed on the second planarization layer 113b sinks into the void around the driving chip PD can be prevented.

Each of the first planarization layer 113a and the second planarization layer 113b can be made of an organic insulating material. However, example embodiments of the present disclosure are not limited thereto. For example, each of the first planarization layer 113a and the second planarization layer 113b can be made of a photoresist, polyimide (PI), or a photo acryl-based material. The protective film 214 can be made of an inorganic insulating material. However, example embodiments of the present disclosure are not limited thereto. For example, the protective film 214 can include silicon nitride (SiNx), silicon oxide (SiOx), or silicon oxynitride (SiOxNy). For example, the protective film 214 can be formed by inorganic film in a single layer or in multiple layers, for example, the inorganic film in a single layer can be a silicon oxide (SiOx) film, a silicon nitride (SiNx) film or silicon oxynitride (SiOxNy) film, and inorganic films in multiple layers can formed by alternately stacking at least one of one or more silicon oxide (SiOx) films, one or more silicon nitride (SiNx) films, and one or more silicon oxynitride (SiOxNy) film, and one or more amorphous silicon (a-Si), but the example embodiments of the present disclosure are not limited thereto.

In order to electrically connect the plurality of light emitting elements 130, 140, and 150 and the plurality of driving chips PD, a plurality of first connection lines 121 can be disposed between the plurality of light emitting elements 130, 140, and 150 and the plurality of driving chips PD. The plurality of driving chips PD can be electrically connected to the plurality of signal lines TL and the plurality of contact electrodes CCE via the plurality of first connection lines 121. For example, the plurality of first connection lines 121 can include the (1-1)-th connection line 121a, the (1-2)-th connection line 121b, the (1-3)-th connection line 121c, and the (1-4)-th connection line 121d. However, example embodiments of the present disclosure are not limited thereto.

The side surface of each of the plurality of light emitting elements 130, 140, and 150 can be covered with the first optical layer 117a. The second electrode CE2 can be disposed on the plurality of light emitting elements 130, 140, and 150 and the first optical layer 117a. The third optical layer 117c in which a plurality of fine particles are dispersed can be disposed on the second electrode CE2.

The black matrix BM can be disposed on the third optical layer 117c. The cover layer 118 can be disposed on the black matrix BM and the third optical layer 117c. The polarizing layer 293 can be disposed on the cover layer 118 via the first adhesive layer 291. The cover member 155 can be disposed on the polarizing layer 293 via the second adhesive layer 295.

The fan-out area FA can be an area in which a plurality of link lines LL1, LL2, LL3, LL4, and LL5 connecting the plurality of first connection lines 121 disposed on the display area AA to the pad area PA are disposed.

The plurality of link lines LL1, LL2, LL3, LL4, and LL5 can include a first link line LL1, a second link line LL2, a third link line LL3, a fourth link line LL4, and a fifth link line LL5. The first link line LL 1, the second link line LL 2, the third link line LL 3, the fourth link line LL 4, and the fifth link line LL 5 can be disposed in different insulating layers.

Each of the plurality of link lines LL1, LL2, LL3, LL4, and LL5 and each of the plurality of first connection lines 121 and each of the plurality of signal lines TL can be formed in the same process and can be disposed in the same layer. For example, the first link line LL1 can be disposed in the same layer as a layer of the (1-1)-th connection line 121a, and the second link line LL2 can be disposed in the same layer as a layer of the (1-2)-th connection line 121b. In addition, the third link line LL3 can be disposed in the same layer as a layer of the (1-3)-th connection line 121c, and the fourth link line LLA can be disposed in the same layer as a layer of the (1-4)-th connection line 121d. In addition, the fifth link line LL5 can be disposed in the same layer as a layer of the signal line TL.

The first link line LL1 can extend to the pad area PA via the bending area BA. However, example embodiments of the present disclosure are not limited thereto. A portion of the first link line LL1 extending to the pad area PA can be the (2-1)-th connection line 122a. The (2-1)-th connection line 122a can be a signal connection line.

A stacked structure including the adhesive layer 112, the first planarization layer 113a, the (2-1)-th connection line 122a, the third planarization layer 114, and the first insulating layer 115a can be disposed in the bending area BA. The bending area BA can have a relatively smaller thickness than that of the fan-out area FA.

The pad area PA can include the (2-2)-th connection line 122b, the (2-3)-th connection line 122c, the (2-4)-th connection line 122d, and the pad electrode PE which are electrically connected to the (2-1)-th connection line 122a extending from the display area AA.

Each of the (2-2)-th connection line 122b, the (2-3)-th connection line 122c, the (2-4)-th connection line 122d, and the pad electrode PE and each of the plurality of first connection lines 121 and each of the plurality of signal lines TL can be formed in the same process and can be disposed in the same layer. For example, the (2-2)-th connection line 122b can be disposed in the same layer as a layer of the (1-2)-th connection line 121b. In addition, the (2-3)-th connection line 122c can be disposed in the same layer as a layer of the (1-3)-th connection line 121c, and the (2-4)-th connection line 122d can be disposed in the same layer as a layer of the (1-4)-th connection line 121d. In addition, the pad electrode PE can be disposed in the same layer as a layer of the signal line TL.

In one example, the thickness of the insulating layers in the tapered area TA can be gradually reduced in order to prevent one or more insulating layers from being delaminated, or having defects such as cracks from occurring during the bending operation of the bending area BA.

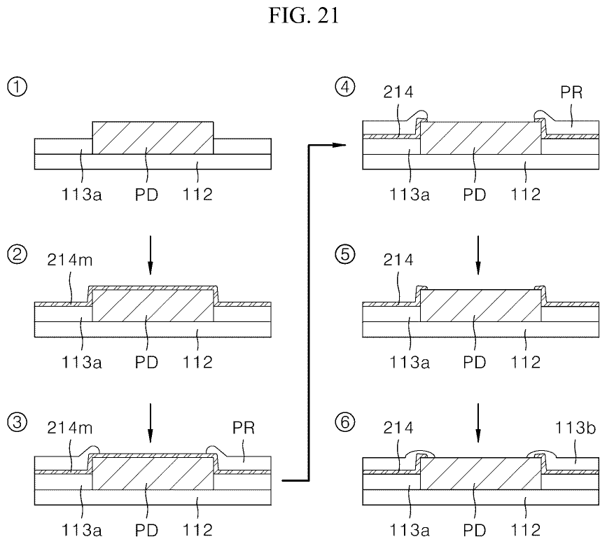

FIG. 21 is a diagram illustrating a method for manufacturing a display device according to an example embodiment of the present disclosure. FIG. 21 illustrates a method for forming the first planarization layer 113a, the protective film 214, and the second planarization layer 113b around the driving chip PD.

Referring to FIG. 21, after the driving chip PD has been disposed on the adhesive layer 112, the first planarization layer 113a can be formed to have a predetermined thickness so as to cover the lower portion of the side surface of the driving chip PD. The first planarization layer 113a can be formed to surround a portion of the side surface of the driving chip PD using a coating process, an exposure process, a development process, and a bake process.

Subsequently, a protective film material 214m can be formed using an atomic layer deposition method so as to cover the upper surface of the first planarization layer 113a and the side and upper surfaces of the driving chip PD. The protective film material 214m can include silicon nitride (SiNx), silicon oxide (SiOx), or silicon oxynitride (SiOxNy). For example, the inorganic film in a single layer or in multiple layers can be formed of the protective film material 214m, for example, the inorganic film in a single layer can be a silicon oxide (SiOx) film, a silicon nitride (SiNx) film or silicon oxynitride (SiOxNy) film, and inorganic films in multiple layers can formed by alternately stacking at least one of one or more silicon oxide (SiOx) films, one or more silicon nitride (SiNx) films, and one or more silicon oxynitride (SiOxNy) film, and one or more amorphous silicon (a-Si), but the example embodiments of the present disclosure are not limited thereto.

Subsequently, a photoresist pattern PR exposing a portion of the planarization film material 214m covering the upper surface of the driving chip PD can be formed. The photoresist pattern PR can cover an edge portion of the upper surface of the driving chip PD.

Subsequently, a portion of the protective film material 214m not covered with the photoresist pattern PR can be removed from the upper surface of the driving chip PD in an etching process. Thus, the protective film 214 according to an example embodiment of the present disclosure can be formed. Subsequently, the photoresist pattern PR can be removed.

Subsequently, the second planarization layer 113b can be formed on the protective film 214. The second planarization layer 113b can be formed to have a predetermined thickness while covering the entirety of the protective film 214. The second planarization layer 113b can cover a portion of the protective film 214 disposed on the edge portion of the upper surface of the driving chip PD. The second planarization layer 113b can be formed to surround the remaining portion of the side surface of the driving chip PD via a coating process, an exposure process, a development process, and a bake process.

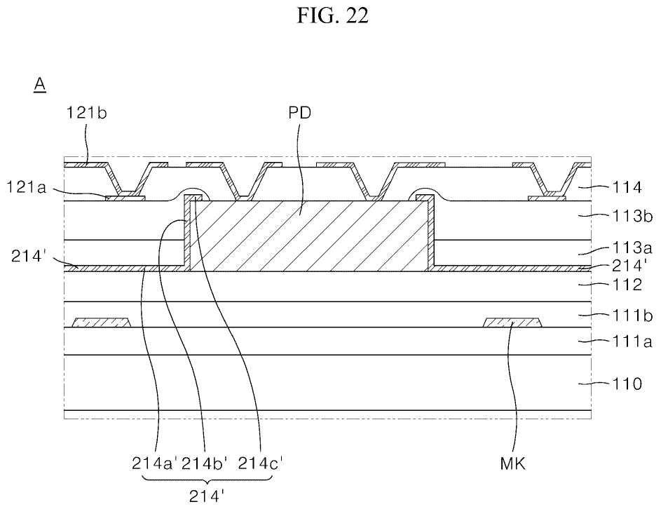

FIG. 22 is a cross-sectional view illustrating a display device according to an example embodiment of the present disclosure, and is a cross-sectional view corresponding to FIG. 19.

Referring to FIG. 22, unlike the example embodiment of FIG. 19, a protective film 214′ can cover an entirety of the side surface of the driving chip PD and is disposed between the adhesive layer 112 and the first planarization layer 113a. The protective film 214′ can be disposed over an entirety of the display area AA. The protective film 214′ can be disposed not only in the display area AA but also in the first non-display area NA1 including the fan-out area FA. In an example embodiment, the protective film 214′ can be additionally disposed in the pad area PA. The protective film 214′ can be disposed between the adhesive layer 112 and the first planarization layer 113a in the pad area PA. The protective film 214′ can be removed from the bending area BA. The protective film 214′ may not be disposed in the bending area BA.

The protective film 214′ can include a first portion 214a′ disposed on the upper surface of the adhesive layer 112, a second portion 214b′ disposed on an entirety of the side surface of the driving chip PD, and a third portion 214c′ disposed on an edge portion of the upper surface of the driving chip PD.

The first planarization layer 113a and the second planarization layer 113b can be stacked on the protective film 214′. The second planarization layer 113b can cover the third portion 214c′ of the protective film 214′ disposed on the edge portion of the upper surface of the driving chip PD.

The protective film 214′ can be made of an inorganic insulating material. However, example embodiments of the present disclosure are not limited thereto. For example, the protective film 214′ can include silicon nitride (SiNx), silicon oxide (SiOx), or silicon oxynitride (SiOxNy). For example, the protective film 214′ can be formed by inorganic film in a single layer or in multiple layers, for example, the inorganic film in a single layer can be a silicon oxide (SiOx) film, a silicon nitride (SiNx) film or silicon oxynitride (SiOxNy) film, and inorganic films in multiple layers can formed by alternately stacking at least one of one or more silicon oxide (SiOx) films, one or more silicon nitride (SiNx) films, and one or more silicon oxynitride (SiOxNy) film, and one or more amorphous silicon (a-Si), but the example embodiments of the present disclosure are not limited thereto.

The protective film 214′ can enhance an adhesive force between the driving chip PD and the second planarization layer 113b, thereby preventing a void from occurring between the driving chip PD and the second planarization layer 113b due to a difference between thermal expansion coefficients of the driving chip PD and the second planarization layer 113b during a subsequent process including a heat treatment process. Since the protective film 214′ prevents the void from being generated between the driving chip PD and the second planarization layer 113b, the structural defect in which a chemical solution used in a manufacturing process or moisture permeates through the void and thus the driving chip PD is damaged, or the third planarization layer 114 disposed on the second planarization layer 113b sinks into the void can be prevented.

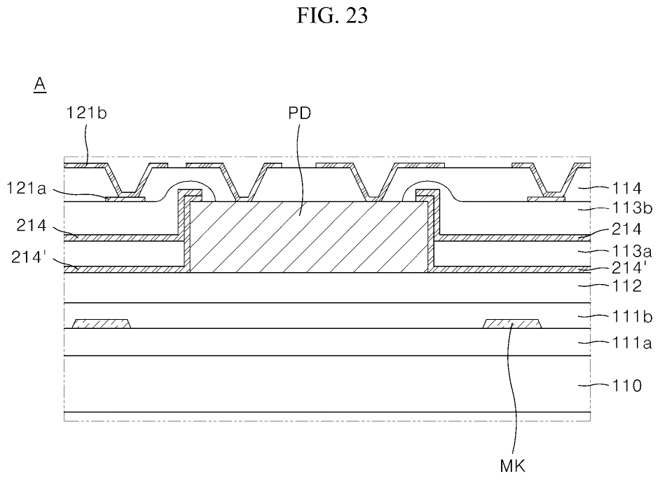

FIG. 23 is a cross-sectional view illustrating a display device according to an example embodiment of the present disclosure, and is a cross-sectional view corresponding to FIG. 19.

Referring to FIG. 23, unlike the example embodiment of FIG. 19, a first protective film 214′ can cover an entirety of the side surface of the driving chip PD and be disposed between the adhesive layer 112 and the first planarization layer 113a. A second protective film 214 can cover a portion of the first protective film 214′ disposed on the upper portion of the side surface of the driving chip PD and be disposed between the first planarization layer 113a and the second planarization layer 113b. Each of the first protective film 214′ and the second protective film 214 can be disposed over an entirety of the display area AA. Each of the first protective film 214′ and the second protective film 214 can be disposed not only in the display area AA but also in the first non-display area NA1 including the fan-out area FA. In an example embodiment, each of the first protective film 214′ and the second protective film 214 can be additionally disposed in the pad area PA. In the pad area PA, the first protective film 214′ can be disposed between the adhesive layer 112 and the first planarization layer 113a, and the second protective film 214 can be disposed between the first planarization layer 113a and the second planarization layer 113b. Each of the first protective film 214′ and the second protective film 214 can be removed from the bending area BA. Each of the first protective film 214′ and the second protective film 214 may not be disposed in the bending area BA.

The first planarization layer 113a can be disposed on the first protective film 214′ so as to have a predetermined thickness, and the protective film 214 can be disposed on the first planarization layer 113a and the first protective film layer 214′. The second planarization layer 113b can be disposed on the second protective film 214. The second planarization layer 113b can cover a portion of the first protective film 214′ and a portion of the second protective film 214 disposed on the edge portion of the upper surface of the driving chip PD. An end of the portion of the first protective film 214′ and an end of a portion of the second protective film 214 disposed on the edge portion of the upper surface of the driving chip PD can coincide with each other or be aligned with each other in the vertical direction.

The first protective film 214′ and the second protective film 214 can enhance an adhesive force between the driving chip PD and the second planarization layer 113b, thereby preventing a void from occurring between the driving chip PD and the second planarization layer 113b due to a difference between thermal expansion coefficients of the driving chip PD and the second planarization layer 113b during a subsequent process including a heat treatment process. Since the first protective film 214′ and the second protective film 214 prevent the void from being generated between the driving chip PD and the second planarization layer 113b, a structural defect in which a chemical solution used in a manufacturing process or moisture permeates through the void and thus the driving chip PD is damaged, or the third planarization layer 114 disposed on the second planarization layer 113b sinks into the void can be prevented.

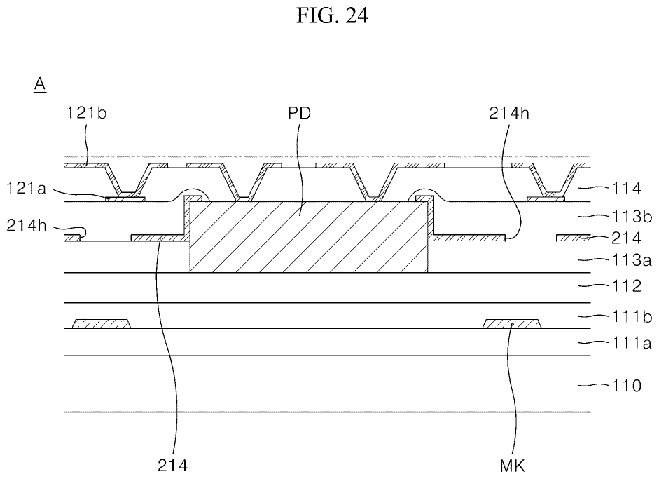

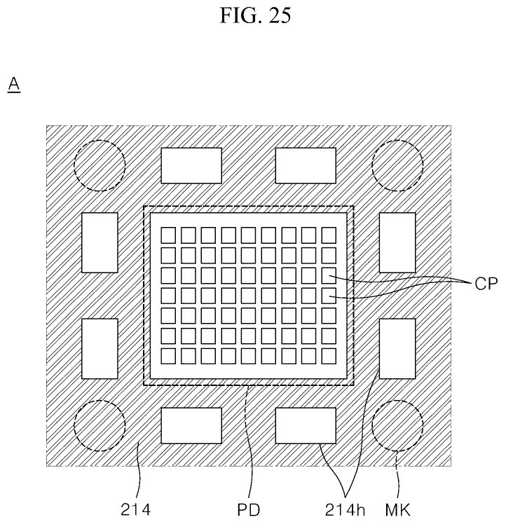

FIG. 24 is a cross-sectional view illustrating a display device according to an example embodiment of the present disclosure, and is a cross-sectional view corresponding to FIG. 19. FIG. 25 is a plan view illustrating a display device according to an example embodiment of the present disclosure, and is a plan view corresponding to FIG. 20.

Referring to FIGS. 24 and 25, the protective film 214 can include a plurality of openings 214h defined therein exposing a portion of the first planarization layer 113a. The second planarization layer 113b can contact the first planarization layer 113a through the plurality of openings 214h. Thus, a plurality of areas formed of organic insulating materials are in direct contact with each other, such that the adhesive force between the second planarization layer 113b and the first planarization layer 113a can be enhanced, and peel-off between the second planarization layer 113b and the first planarization layer 113a can be prevented.

The plurality of openings 214h can be regularly arranged. However, example embodiments of the present disclosure are not limited thereto. Although each of the plurality of openings 214h is shown as having a quadrangular shape in the plan view of FIG. 25, example embodiments of the present disclosure are not limited thereto. For example, each of the plurality of openings 214h can be polygonal, circular, elliptical, or the like in the plan view.

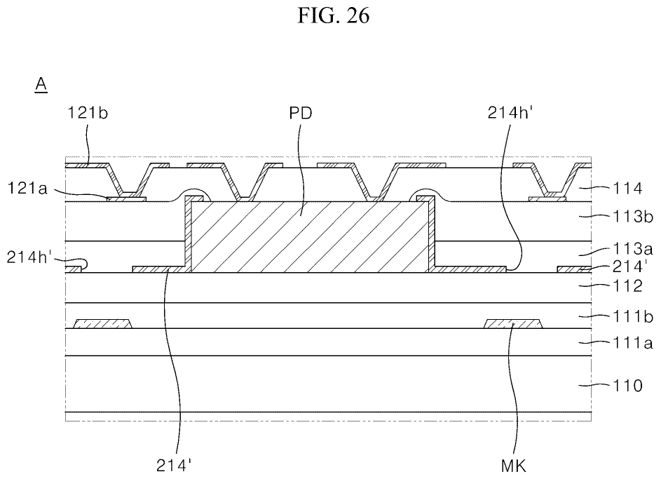

FIG. 26 is a cross-sectional view illustrating a display device according to an example embodiment of the present disclosure, and is a cross-sectional view corresponding to FIG. 22.

Referring to FIG. 26, the protective film 214′ can include a plurality of openings 214h′ defined therein that expose a portion of the adhesive layer 112. The first planarization layer 113a can be in contact with the adhesive layer 112 through the plurality of openings 214h′. Thus, a plurality of areas formed of organic insulating materials are in direct contact with each other, such that the adhesion force between the first planarization layer 113a and the adhesive layer 112 can be enhanced, and peel-off between the first planarization layer 113a and the adhesive layer 112 can be prevented.

The plurality of openings 214h′ can be regularly arranged. However, example embodiments of the present disclosure are not limited thereto. Each of the plurality of openings 214h′ can have a quadrangular shape in a plan view. However, example embodiments of the present disclosure are not limited thereto. For example, a shape in the plan view of each of the plurality of openings 214h′ can be polygonal, circular, elliptical, or the like.

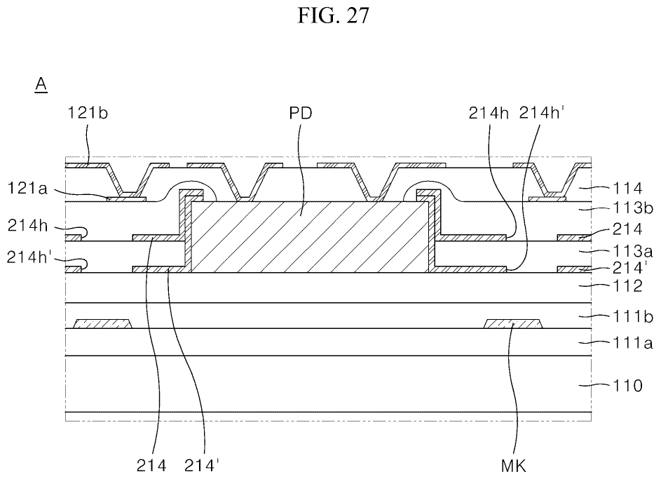

FIG. 27 is a cross-sectional view illustrating a display device according to an example embodiment of the present disclosure, and is a cross-sectional view corresponding to FIG. 23.

Referring to FIG. 27, the first protective film 214′ can include a plurality of openings 214h′ defined therein exposing a portion of the adhesive layer 112, and the first planarization layer 113a can be in contact with the adhesive layer 112 through the plurality of openings 214h′. In addition, the protective film 214 can include a plurality of openings 214h defined therein exposing a portion of the first planarization layer 113a, and the second planarization layer 113b can be in contact with the first planarization layer 113a through the plurality of openings 214h. Each of the plurality of openings 214h′ and each of the plurality of openings 214h can overlap each other in the vertical direction. However, example embodiments of the present disclosure are not limited thereto.

Thus, the plurality of areas formed of organic insulating materials are in direct contact with each other, such that the adhesive force between the first planarization layer 113a and the adhesive layer 112 and the adhesive force between the second planarization layer 113b and the first planarization layer 113a can be enhanced, and thus, the peeling-off between the first planarization layer 113a and the adhesive layer 112 and the peeling-off between the second planarization layer 113b and the first planarization layer 113a can be prevented.

The display device according to various aspects and example embodiments of the present disclosure can be described as follows.

One aspect of the present disclosure provides a display device comprising: a substrate; an adhesive layer disposed on the substrate; a driving chip disposed on the adhesive layer; a first planarization layer disposed on the adhesive layer so as to surround a lower portion of a side surface of the driving chip; a second planarization layer disposed on the first planarization layer so as to surround an upper portion of the side surface of the driving chip; and at least one protective film disposed between the second planarization layer and the driving chip so as to cover at least the upper portion of the side surface of the driving chip.

In accordance with some example embodiments of the present disclosure, the protective film covers the upper portion of the side surface of the driving chip and is disposed between the first planarization layer and the second planarization layer.

In accordance with some example embodiments of the present disclosure, the protective film covers an entirety of the side surface of the driving chip and is disposed between the adhesive layer and the first planarization layer.

In accordance with some example embodiments of the present disclosure, a portion of the protective film is disposed on an edge portion of an upper surface of the driving chip, wherein the second planarization layer covers a portion of the protective film disposed on the edge portion of the upper surface of the driving chip.

In accordance with some example embodiments of the present disclosure, each of the first planarization layer and the second planarization layer is made of an organic insulating material, and the protective film is made of an inorganic insulating material.

In accordance with some example embodiments of the present disclosure, the inorganic insulating material includes silicon nitride, silicon oxide, or silicon oxynitride.

In accordance with some example embodiments of the present disclosure, organic insulating material includes a photoresist, polyimide PI, or photo acryl-based material.

In accordance with some example embodiments of the present disclosure, the protective film has a plurality of openings defined therein exposing a portion of the first planarization layer, wherein the second planarization layer is in contact with the first planarization layer through the plurality of openings.

In accordance with some example embodiments of the present disclosure, the protective film has a plurality of openings defined therein exposing a portion of the adhesive layer, wherein the first planarization layer is in contact with the adhesive layer through the plurality of openings.

In accordance with some example embodiments of the present disclosure, the at least one protective film includes: a first protective film covering an entirety of the side surface of the driving chip and disposed between the adhesive layer and the first planarization layer; and a second protective film covering a portion of the first protective film on the upper portion of the side surface of the driving chip and disposed between the first planarization layer and the second planarization layer.

In accordance with some example embodiments of the present disclosure, a portion of the first protective film is disposed on an edge portion of an upper surface of the driving chip, wherein a portion of the second protective film covers the portion of the first protective film disposed on the edge portion of the upper surface of the driving chip.

In accordance with some example embodiments of the present disclosure, a side end of the portion of the first protective film and a side end of the portion of the second protective film are aligned with each other on the edge portion of the upper surface of the driving chip.

In accordance with some example embodiments of the present disclosure, the second planarization layer covers the portion of the first protective film and the portion of the second protective film disposed on the edge portion of the upper surface of the driving chip.

In accordance with some example embodiments of the present disclosure, the first protective film has a plurality of first openings defined therein exposing a portion of the adhesive layer, wherein the first planarization layer is in contact with the adhesive layer through the plurality of first openings, wherein the second protective film has a plurality of second openings defined therein exposing a portion of the first planarization layer, wherein the second planarization layer is in contact with the first planarization layer through the plurality of second openings.

In accordance with some example embodiments of the present disclosure, each of the first planarization layer and the second planarization layer is made of an organic insulating material, wherein each of the first protective film and the second protective film is made of an inorganic insulating material.

In accordance with some example embodiments of the present disclosure, the display device further comprises: a bank disposed on the driving chip; a first electrode disposed on the bank and electrically connected to the driving chip; and a light-emitting element disposed on the first electrode.

In accordance with some example embodiments of the present disclosure, the driving chip is a micro driver, and the light-emitting element is a micro light-emitting element.

In accordance with some example embodiments of the present disclosure, the micro light-emitting element has a vertical structure.

In accordance with some example embodiments of the present disclosure, the light-emitting element is bonded to and electrically connected to the first electrode via eutectic bonding.

In accordance with some example embodiments of the present disclosure, the at least one protective film includes a first protective film, wherein the first protective film includes a first portion disposed on an upper surface of the adhesive layer, a second portion disposed on an entirety of the side surface of the driving chip, and a third portion disposed on an edge portion of the upper surface of the driving chip.

In accordance with some example embodiments of the present disclosure, a plurality of first openings are formed at the first portion of the first protective film to expose a portion of the adhesive layer, and the first planarization layer is in contact with the adhesive layer through the plurality of first openings.

In accordance with some example embodiments of the present disclosure, the at least one protective film includes a second protective film, wherein the second protective film includes a first portion disposed on an upper surface of the first planarization layer, a second portion disposed on the upper portion of the side surface of the driving chip, and a third portion disposed on an edge portion of the upper surface of the driving chip.

In accordance with some example embodiments of the present disclosure, a plurality of second openings are formed at the first portion of the second protective film to expose a portion of the first planarization layer, and the second planarization layer is in contact with the first planarization layer through the plurality of second openings.

Another aspect of the present disclosure provides a manufacture method of a display device including: forming a substrate; forming an adhesive layer over the substrate; forming a driving chip on the adhesive layer; forming a first planarization layer on the adhesive layer so as to surround a lower portion of a side surface of the driving chip; and forming a second planarization layer on the first planarization layer so as to surround an upper portion of the side surface of the driving chip, wherein at least one protective film is formed between the second planarization layer and the driving chip so as to cover at least the upper portion of the side surface of the driving chip.

Although some example embodiments of the present disclosure have been described above with reference to the accompanying drawings, the present disclosure may not be limited to some example embodiments and can be implemented in various different forms. Those of ordinary skill in the technical field to which the present disclosure belongs will be able to appreciate that the present disclosure can be implemented in other specific forms without changing the technical idea or essential features of the present disclosure. Therefore, it should be understood that some example embodiments as described above are not restrictive but illustrative in all respects.

What is claimed is:

1. A display device comprising:
a substrate;
an adhesive layer disposed on the substrate;
a driving chip disposed on the adhesive layer;
a first planarization layer disposed on the adhesive layer so as to surround a lower portion of a side surface of the driving chip;
a second planarization layer disposed on the first planarization layer so as to surround an upper portion of the side surface of the driving chip; and
at least one protective film disposed between the second planarization layer and the driving chip so as to cover at least the upper portion of the side surface of the driving chip.

2. The display device of claim 1, wherein the at least one protective film covers the upper portion of the side surface of the driving chip and is disposed between the first planarization layer and the second planarization layer, or
wherein the at least one protective film covers an entirety of the side surface of the driving chip and is disposed between the adhesive layer and the first planarization layer.

3. The display device of claim 1, wherein a portion of the at least one protective film is disposed on an edge portion of an upper surface of the driving chip, and
wherein the second planarization layer covers a portion of the at least one protective film disposed on the edge portion of the upper surface of the driving chip.

4. The display device of claim 1, wherein each of the first planarization layer and the second planarization layer includes an organic insulating material, and the at least one protective film includes an inorganic insulating material.

5. The display device of claim 4 wherein the inorganic insulating material includes silicon nitride, silicon oxide, or silicon oxynitride, or
wherein the organic insulating material includes a photoresist, polyimide PI, or photo acryl-based material.

6. The display device of claim 2, wherein the at least one protective film has a plurality of openings defined therein exposing a portion of the first planarization layer, and
wherein the second planarization layer is in contact with the first planarization layer through the plurality of openings.

7. The display device of claim 2, wherein the at least one protective film has a plurality of openings defined therein exposing a portion of the adhesive layer, and
wherein the first planarization layer is in contact with the adhesive layer through the plurality of openings.

8. The display device of claim 1, wherein the at least one protective film includes:
a first protective film covering an entirety of the side surface of the driving chip, and disposed between the adhesive layer and the first planarization layer; and
a second protective film covering a portion of the first protective film disposed on the upper portion of the side surface of the driving chip, and disposed between the first planarization layer and the second planarization layer.

9. The display device of claim 8, wherein a portion of the first protective film is disposed on an edge portion of an upper surface of the driving chip, and
wherein a portion of the second protective film covers the portion of the first protective film disposed on the edge portion of the upper surface of the driving chip.

10. The display device of claim 9, wherein an end of the portion of the first protective film and an end of the portion of the second protective film are aligned with each other on the edge portion of the upper surface of the driving chip, or
wherein the second planarization layer covers the portion of the first protective film and the portion of the second protective film disposed on the edge portion of the upper surface of the driving chip.

11. The display device of claim 8, wherein the first protective film has a plurality of first openings defined therein exposing a portion of the adhesive layer, and the first planarization layer is in contact with the adhesive layer through the plurality of first openings, and
wherein the second protective film has a plurality of second openings defined therein exposing a portion of the first planarization layer, and the second planarization layer is in contact with the first planarization layer through the plurality of second openings.

12. The display device of claim 1, wherein the display device further comprises:
a bank disposed on the driving chip;
a first electrode disposed on the bank and electrically connected to the driving chip; and
a light-emitting element disposed on the first electrode,
wherein the driving chip is a micro driver, and the light-emitting element is a micro light-emitting element having a vertical structure.

13. The display device of claim 12, wherein the light-emitting element is bonded to and electrically connected to the first electrode via eutectic bonding.

14. The display device of claim 1, wherein the at least one protective film includes a first protective film, and
wherein the first protective film includes a first portion disposed on an upper surface of the adhesive layer, a second portion disposed on an entirety of the side surface of the driving chip, and a third portion disposed on an edge portion of the upper surface of the driving chip.

15. The display device of claim 14, wherein a plurality of first openings are formed at the first portion of the first protective film to expose a portion of the adhesive layer, and
wherein the first planarization layer is in contact with the adhesive layer through the plurality of first openings.

16. The display device of claim 1, wherein the at least one protective film includes a second protective film, and
wherein the second protective film includes a first portion disposed on an upper surface of the first planarization layer, a second portion disposed on the upper portion of the side surface of the driving chip, and a third portion disposed on an edge portion of the upper surface of the driving chip.

17. The display device of claim 16, wherein a plurality of second openings are formed at the first portion of the second protective film to expose a portion of the first planarization layer, and
wherein the second planarization layer is in contact with the first planarization layer through the plurality of second openings.

18. A manufacture method for a display device, the manufacturing method comprising:
forming a substrate;
forming an adhesive layer on the substrate;
forming a driving chip on the adhesive layer;
forming a first planarization layer on the adhesive layer so as to surround a lower portion of a side surface of the driving chip; and
forming a second planarization layer on the first planarization layer so as to surround an upper portion of the side surface of the driving chip,
wherein at least one protective film is formed between the second planarization layer and the driving chip so as to cover at least the upper portion of the side surface of the driving chip.

19. The manufacture method of claim 18, wherein the at least one protective film includes a first protective film, and the first protective film includes a first portion disposed on an upper surface of the adhesive layer, a second portion disposed on an entirety of the side surface of the driving chip, and a third portion disposed on an edge portion of the upper surface of the driving chip, or
wherein the at least one protective film includes a second protective film, and the second protective film includes a first portion disposed on an upper surface of the first planarization layer, a second portion disposed on the upper portion of the side surface of the driving chip, and a third portion disposed on an edge portion of the upper surface of the driving chip.

20. The manufacture method of claim 19, wherein a plurality of first openings are formed at the first portion of the first protective film to expose a portion of the adhesive layer, and the first planarization layer is in contact with the adhesive layer through the plurality of first openings, or
wherein a plurality of second openings are formed at the first portion of the second protective film to expose a portion of the first planarization layer, and the second planarization layer is in contact with the first planarization layer through the plurality of second openings.
